(19) United States
(12) Patent Application Publication
(10) Pub. No.: US 2003/0014862 A1
(43) Pub. Date: Jan. 23, 2003

(54) Electric-component mounting method and system

(75) Inventors: Shinsuke Suhara, Kariya-shi (JP); Yukio Ueno, Nagoya-shi (JP); Akiyoshi Tanaka, Handa-shi (JP)

Correspondence Address: OLIFF & BERRIDGE, PLC, P.O. BOX 19928, ALEXANDRIA, VA, 22320, US

(73) Assignee: FUJI MACHINE MFG. CO., LTD., Chiryu-shi (JP)

(21) Appl. No.: 10/193,604

(22) Filed: Jul. 12, 2002

(30) Foreign Application Priority Data
Jul. 17, 2001 (JP) 2001-217230

(51) Int. Cl. H05K 3/30; B23P 19/00

(52) U.S. Cl. 29/832; 29/743; 29/740; 29/834

(57) ABSTRACT

Method of mounting an electric component on a component-mounting surface such that the electric component held by a suction nozzle under a negative pressure is forced onto the component-mounting surface, with termination of application of the negative pressure to the suction nozzle, and the suction nozzle is then moved away from the component-mounting surface, the method comprising the steps of: initiating application of a positive pressure to a passage communicating with the suction nozzle, before the electric component is forced onto the component-mounting surface; maintaining the application of the positive pressure to the passage, until the suction nozzle is spaced apart from the electric component by at least 0.4 mm; and then exposing the passage to the atmosphere. Also disclosed is an electric-component mounting system arranged to practice the method.

This application is based on Japanese Patent Application No. 2001-217230 filed on Jul. 17, 2001, the contents of which are incorporated hereinto by reference.

### BACKGROUND OF THE INVENTION

1. Field of the Invention

The present invention relates in general to a method and an apparatus for mounting an electric component (typically an electronic component) on a component-mounting surface, and more particularly to techniques for mounting an electric component by using a suction nozzle.

2. Discussion of Related Art

A suction nozzle is arranged to hold an electric component by suction under a negative pressure, and is used to mount the electric component on a component-mounting surface, in an electric-component mounting system as disclosed in U.S. Pat. No. 6,161,277. In this electric-component mounting system, a plurality of suction nozzles are disposed on an indexing body rotatable about its axis, such that the suction nozzles are equiangularly spaced apart from each other in the rotating direction of the indexing body. These suction nozzles are sequentially moved to and stopped at a plurality of working positions, by a rotation motion of the indexing body. The working positions include a component-receiving position at which each suction nozzles is lowered and elevated by a first nozzle elevating and lowering device, to receive the electric component from a component-supplying device, and a component-mounting position at which each suction nozzle holding the electric component received from the component-supplying device is lowered and elevated by a second nozzle elevating and lowering device, to mount the electric component on the component-mounting surface of a printed-wiring board. The indexing body and a rotary drive device to rotate the indexing body are disposed on a moving device which is movable between the component-supplying device and the printed-wiring board, so that the plurality of suction nozzles are operated to mount the respective electric components at respective component-mounting spots on the component-mounting surface.

A negative pressure is applied to each suction nozzle when the electric component is held by the suction nozzle, and an atmospheric pressure is applied to the suction nozzle when the electric component is mounted on the component-mounting surface. The indexing body carries a directional control valve for each of the suction nozzles. At each of the component-receiving and component-mounting positions, there are provided the above-indicated nozzle elevating and lowering device, and a valve switching device which is arranged to mechanically switch the directional control valve in synchronization with the downward and upward movements of the suction nozzle. The first valve switching device provided at the component-receiving position has a switching member which comes into abutting contact with a spool of the direction control valve, to move the spool in one direction for switching this valve from an atmospheric-pressure applying state to a negative-pressure applying state when the suction nozzle is lowered to hold the electric component by suction. The second valve switching device provided at the component-mounting position has a switching member which comes into abutting contact with the spool of the directional control valve, to move the spool in the reverse direction for switching the directional control valve from the negative-pressure applying state to the atmospheric-pressure applying state when the suction nozzle is lowered to mount the electric component on the component-mounting surface. Further, a positive pressure of compressed air is applied to the suction nozzle through the second valve switching device placed in its atmospheric-pressure applying state, and the spool of the directional control valve, so that the pressure applied to the suction nozzle rapidly changes from the negative pressure to the positive pressure, to permit the suction nozzle to release the electric component in a short time.

However, the known electric-component mounting system described above suffers from a risk that the electric component once placed on the printed-wiring board is sucked again by the suction nozzle, and is moved with the suction nozzle away from the board. Namely, when the application of the positive pressure to the suction nozzle is terminated to expose the suction nozzle to the atmosphere after the electric component is placed on the printed-wiring board, there may arise pressure pulsation upon reduction of the pressure from the positive pressure to the atmospheric pressure, which pressure pulsation may cause generation of a negative pressure and a consequent attraction force with which the electric component may be sucked again by the suction nozzle.

This problem may take place not only in the electric-component mounting system of the type as disclosed in the above-described U.S. Pat. No. 6,161,277, but also in electric-component mounting systems of other types, and may also take place in operations other than normal component-mounting operations, for instance, in an operation to place reference electric components at predetermined mounting spots on a component-mounting surface, for the purpose of detecting positioning errors of suction nozzles, for example, in an electric-component mounting system.

### SUMMARY OF THE INVENTION

The present invention was made in view of the background art discussed above. It is a first object of the present invention to provide an electric-component mounting method which permits an improved degree of stability in mounting an electric component on a component-mounting surface, with application of a positive pressure to a suction nozzle to release the electric component in a short time. The first or second object indicated above may be achieved according to the following modes of the present invention in the form of an electric-component mounting method or system. Each of the following modes of the invention is numbered like the appended claims and depends from the other mode or modes, where appropriate, to indicate and clarify possible combinations of elements or technical features. It is to be understood that the present invention is not limited to the technical features or any combinations thereof which will be described for illustrative purpose only. It is to be further understood that a plurality of elements or features included in any one of the following modes of the invention are not necessarily provided all together, and that the invention may be embodied without some of the elements or features described with respect to the same mode.

(1) A method of mounting an electric component on a component-mounting surface such that the electric component held by a suction nozzle by suction under a negative pressure is forced onto the component-mounting surface, with termination of application of the negative pressure to the suction nozzle, and the suction nozzle is then moved away from the component-mounting surface, the method comprising the steps of initiating application of a positive pressure to a passage communicating with the suction nozzle, before the electric component is forced onto the component-mounting surface; maintaining the application of the positive pressure to the passage, until the suction nozzle is spaced apart from the electric component by at least 0.4 mm; and then exposing the passage to the atmosphere.

The component-mounting surface on which the electric component is mounted is a surface of a circuit substrate on which a printed circuit may or may not be formed, or a surface of a test substrate on which electric components are mounted for any inspection purpose relating to the mounting of the electric components.

The minimum required distance of movement of the suction nozzle away from the electric component for which the application of the positive pressure to the suction nozzle is maintained or continued is 0.4 mm, preferably, 0.5 mm, 0.6 mm, or 0.8 mm.

The application and removal of the negative pressure to and from the suction nozzle, and the application and removal of the atmospheric pressure to and from the suction nozzle may be controlled mechanically or electrically in synchronization with the movements of the suction nozzle toward and away from the component-mounting surface. The method according to the following mode (2) of the invention is an example of the mechanical control. An example of the electric control uses a solenoid-operated valve which is electrically switched to apply and remove the negative pressure to and from the suction nozzle, for instance.

Where the application of the positive pressure to the suction nozzle is terminated and the suction nozzle is exposed to the atmosphere when the suction nozzle is located at a position which is distant from the electric component by at least 0.4 mm, there is not a risk that the electric component is sucked again by the suction nozzle under a negative pressure which may be generated due to pressure pulsation upon changing of the suction nozzle pressure from the positive pressure to the atmospheric pressure. Accordingly, the electric component released from the suction nozzle by application of the positive pressure to the suction nozzle can be mounted on the component-mounting surface with improved stability.

(2) A method of mounting an electric component on a component-mounting surface, wherein a suction nozzle holding the electric component by suction under a negative pressure is lowered by a nozzle elevating and lowering device, to force the electric component onto the component-mounting surface, such that the nozzle elevating and lowering device moves at least one of a directional control valve and a switching member to move the directional control valve and the switching member toward each other, for thereby causing the switching member to switch the directional control valve from a negative-pressure applying state for applying the negative pressure to the suction nozzle, to an atmospheric-pressure applying state for applying an atmospheric pressure to the suction nozzle, and wherein the suction nozzle is subsequently elevated by the nozzle elevating and lowering device such that the nozzle elevating and lowering device moves the directional control valve and the switching member away from each other, the method comprising the steps of: initiating application of a positive pressure to the suction nozzle, when the directional control valve is switched from the negative-pressure applying state to the atmospheric-pressure applying state; and maintaining the application of the positive pressure to the suction nozzle, even after the directional control valve and the switching member have been moved away from each other as a result of initiation of an operation of the nozzle elevating and lower device to elevate the suction nozzle.

The application of -the positive pressure to the suction nozzle may be initiated at the moment when the directional control valve is switched from the negative-pressure applying state to the atmospheric-pressure applying state, while the directional control valve is still placed in the negative-pressure applying state, or after the directional control valve has been switched to the atmospheric-pressure applying state.

The directional control valve switched to the atmospheric-pressure applying device is kept in this atmospheric-pressure applying device, even with the switching member spaced apart from the directional control valve, until the directional control valve is switched to the negative-pressure applying device when the suction nozzle is again lowered to mount the next electric component. While the directional control valve is placed in the atmospheric-pressure applying state, the positive pressure is kept applied to the suction nozzle through the directional control valve, for a predetermined time, so that when the application of the positive pressure is terminated, the suction nozzle is spaced apart from the electric component by a larger distance than when the switching member and the directional control valve were moved away from each other. This distance is sufficient to prevent the electric component from being sucked again by the suction nozzle even if a negative pressure is generated immediately after the moment of termination of the application of the positive pressure.

The predetermined time during which the application of the positive pressure to the suction nozzle is maintained is determined to assure prevention of suction of the electric component by the suction nozzle due to a negative pressure that may be generated upon exposure of the suction nozzle to the atmosphere. This time is suitably determined depending upon the velocity of the upward and downward movements of the suction nozzle, preferably, to be at least 1 ms, or at least 2 ms or 3 ms, in general.

In the method according to the mode (2) described above, the switching of the directional control valve by the switching member is mechanically linked with the movements of the suction nozzle by the nozzle elevating and lowering device. Where the electric components are mounted at respective predetermined component-mounting spots on a surface of a circuit-substrate (one form of the above-indicated component-mounting surface), for instance, each electric component is required to be mounted on the circuit substrate at a high speed if the required cycle time to mount the electric components (which is a time length between successive moments of mounting of two electric components) is accordingly short. In this case, too, the directional control valve can be switched in precise synchronization with the movements of the suction nozzle. Further, since the application of the positive pressure to the suction nozzle is continued for the predetermined time after the switching member and the directional control valve have been moved away from each other, the electric component is effectively prevented from being sucked again by the suction nozzle, without having to increase the operating cycle time. Thus, the present method permits efficient mounting of the electric components on the circuit substrate, without a risk of suction of the electric components by the suction nozzles after the electric components are once placed on the circuit substrate. The suction of the electric component by the suction nozzle after the mounting on the circuit substrate can be avoided by slowing moving the suction nozzle away from the electric component, that is, by reducing the acceleration value of the suction nozzle during its movement away from the electric component already placed on the component-mounting surface. However, this solution causes an undesirable increase of the operating cycle time. In this respect, the method according to the above mode (2) is advantageous in that the suction of the electric component by the suction nozzle after the electric component is once placed on the circuit substrate can be avoided with high stability, without having to reduce the acceleration value of the suction nozzle during its upward movement away from the electric component, that is, without having to increase the operating cycle time.

(3) A method according to the above mode (2), wherein the directional control valve is switched between the negative-pressure and atmospheric-pressure applying states by the switching member, by movements of the directional control valve by the nozzle elevating and lowering device while the switching member is held stationary.

In the mode (2) described above, the directional control valve is switched by movements of the directional control valve by the nozzle elevating and lowering device provided to elevate and lower the suction nozzle for which the directional control valve is provided. This arrangement eliminates a need of providing a relative movement device exclusively designed to move the directional control valve and the switching device relative to each other.

(4) An electric-component mounting system for mounting an electric component on a component-mounting surface, comprising:

a suction nozzle operable to hold the electric component by suction under a negative pressure;

a nozzle elevating and lowering device operable to elevate and lower the suction nozzle to place the electric component on the component-mounting surface;

a negative pressure source operable to generate the negative pressure;

a directional control valve provided in a connecting passage connecting the negative pressure source and the suction nozzle, and having at least a negative-pressure applying state for applying the negative pressure from the negative pressure source to the suction nozzle, and an atmospheric-pressure applying state for applying an atmospheric pressure to the suction nozzle;

a valve switching device including a switching member which is positioned relative to the directional control valve such that the nozzle elevating and lowering device moves at least one of the directional control valve and the switching member to move the directional control valve and the switching member toward each other, for thereby causing the switching member to switch the directional control valve from the negative-pressure applying state to the atmospheric-pressure applying state, in synchronization with a movement of the suction nozzle by the nozzle elevating and lowering device; and

a positive-pressure applying device including a positive pressure source operable to generate a positive pressure, and operable to initiate application of the positive pressure to the suction nozzle, when the directional control valve is switched from the negative-pressure applying state to the atmospheric-pressure applying state, the positive-pressure applying device maintaining the application of the positive pressure to the suction nozzle, for a predetermined time after the directional control valve and the switching member have been moved away from each other as a result of initiation of an operation of the nozzle elevating and lowering device to elevate the suction nozzle.

The electric-component mounting system constructed according to the above mode (4) of this invention has advantages such as those described above with respect to the method according to the above mode (2). The nozzle elevating and lowering device may use as a drive source an electric motor, or a fluid-operated actuator such as a fluid-actuator cylinder, for instance, an air cylinder.

(5) An electric-component mounting system according to the above mode (4), wherein the positive-pressure applying device includes:

a first connecting portion formed at an upstream end of a downstream passage connected to the suction nozzle;

a second connecting portion formed at a downstream end of an upstream passage connected to the positive pressure source, said connecting passage consisting of said downstream and upstream passages; and

a communication control device operable by the nozzle elevating and lowering device, when the directional control valve is switched from the negative-pressure applying state to the atmospheric-pressure applying sate, to effect an abutting contact of the first and second connecting portions with each other for communication of the upstream and downstream passages with each other, the communication control device maintaining the application of the positive pressure to the suction nozzle for the predetermined time after the directional control valve and the switching member have been moved away from each other.

While the first and second connecting portions of the communication control device are placed in abutting contact with each other, the positive pressure is applied to the suction nozzle through the first and second connecting portions. These two connecting portions are held in abutting contact with each other for the predetermined time even after the directional control valve and the switching member have been moved away from each other, so that the pressure applied to the suction nozzle is kept at a positive value for the predetermined time even after the movement of the suction nozzle away from the electric component by the nozzle elevating and lowering device is initiated.

(6) An electric-component mounting system according to the above mode (4), wherein the directional control valve includes: a housing; and a spool disposed within the housing, movably by the switching member relative to the housing, to selectively establish the negative-pressure applying state and said atmospheric-pressure applying state.

(7) An electric-component mounting system according to the above mode (6), wherein the housing includes a first connecting portion having a positive-pressure passage which communicates with a downstream passage connected to the suction nozzle, the positive-pressure passage being formed in the first connecting portion such that the positive-pressure passage is open in the first connecting portion to apply the positive pressure to the suction nozzle through the positive-pressure passage and the downstream passage.

In the electric-component mounting system according to the above mode (7), the first connecting portion having the positive-pressure passage is provided by the housing of the directional control valve, so that the positive-pressure applying device can be made simple in construction.

(8) An electric-component mounting system according to the above mode (7), wherein the valve switching device includes: the switching member; and a holding member for holding the switching member such that the holding member and the housing of the directional control valve are moved relative to each other by the nozzle elevating and lowering device, the holding member being provided with a second connecting portion having a surface for abutting contact with a surface of the first connecting portion in which the positive-pressure passage is open.

(9) An electric-component mounting system according to the above mode (8), wherein each of at least one of the first and second connecting portions consists of a movable connector member which is movable in a direction of relative movement of the directional control valve and the switching member, relative to a member which holds at least one of the housing and the holding member.

(10) An electric-component mounting system according to the above mode (9), wherein the positive-pressure applying device includes a biasing device for biasing the movable connector member in a direction toward the other of the first and second connecting portions, and a stop device for defining a fully advanced position at which the movable connector member is held under a biasing action of the biasing device, the fully advanced position being such that the movable connector member and the other of the first and second connecting portions are held in abutting contact with each other even after the switching member and the spool of the directional control valve have been moved away from each other during the relative movement of the holding member and the housing away from each other.

In the known positive-pressure applying device, the application of the positive pressure to the suction nozzle is terminated when the switching member has been moved away from the spool of the directional control valve. Since the valve switching device is operated by the nozzle elevating and lowering device, a moment of relative movement of the switching member and the spool away from each other and a moment of a movement of the suction nozzle away from the electric component have a predetermined constant relationship. In other words, the moment of termination of the application of the positive pressure to the suction nozzle cannot be changed, as needed, with respect to the moment of the movement of the suction nozzle away from the electric component. In the electric-component mounting system according to the above mode (10), the movable connector member serving as one of the first and second connecting portions, and the other connecting portion are held in abutting contact with each other even after the switching member and the spool of the directional control valve have been moved away from each other during the relative movement of the holding member and the housing away from each other. This arrangement permits the application of the positive pressure to the suction nozzle even after the switching member and the spool have been moved away from each other. In this respect, it is noted that the moment at which the movable connector member is moved away from the other connecting portion can be delayed, as needed, with respect to the moment at which the switching member and the spool are moved away from each other, so that the moment of termination of the application of the positive pressure to the suction nozzle can be delayed as needed, with respect to the moment at which the suction nozzle is moved away from the electric component. Thus, the arrangement according to the above mode (10) assures a sufficient distance between the suction nozzle and the electric component when the application of the positive pressure to the suction nozzle is terminated.

(11) An electric-component mounting system according to the above mode (8), wherein the switching member is held by the holding member such that the switching member is movable relative to the holding member.

(12) An electric-component mounting system according to the above mode (11), wherein the valve switching device further includes a biasing device disposed between the switching member and the holding member, for biasing the switching member in a direction toward the spool of the directional control valve, and a stopper device for defining a fully advanced position at which the switching member is held under a biasing action of the biasing device.

(13) An electric-component mounting system according to the above mode (9), wherein the second connecting portion consists of the movable connector member movable relative to the holding member.

The second connecting portion consisting of the movable connector member movable relative to the holding member is advantageously provided in an electric-component mounting system which has a plurality of suction nozzles which are successively moved to a predetermined component-mounting position of the system, to mount the respective electric components at respective component-mounting spots on the component-mounting surface. In this system, the suction nozzles are provided with respective directional control valves, and the valve switching device is disposed at the component-mounting position, so that each of the directional control valves is switched by the valve switching device. Further, the positive-pressure applying device is arranged to apply the positive pressure to each suction nozzle. According to the above mode (13) wherein the second connecting portion consists of the movable connector member movable relative to the holding member, the first connecting portion need not be movable relative to the housing of each directional control valve, that is, may be fixedly provided on the housing. Accordingly, the positive-pressure applying device provided in the system according to the above mode (13) can be made simpler in construction than a positive-pressure applying device wherein the first connecting portion provided on the housing of each of the directional control valves consists of the movable connector member movable relative to the housing.

(14) An electric-component mounting system according to the above mode (13), wherein the switching member is held by the holding member such that the switching member is movable relative to the holding member, and the movable connector member is held by the switching member such that the movable connector member is movable relative to the switching member, in a direction of the relative movement of the switching member and the holding member.

(15) An electric-component mounting system according to the above mode (14), wherein the switching member includes a cylindrical hollow portion at which the switching member is held by the holding member, and the movable connector member is movably fitted in the cylindrical hollow portion.

In the electric-component mounting system according to the above mode (15), a portion of the positive-pressure applying device is incorporated in or provided by the switching member, so that the positive-pressure applying device can be made relatively compact in construction.

(16) An electric-component mounting system according to the above mode (15), wherein the valve switching device includes a first biasing device for biasing the switching member, and the positive-pressure applying device includes a second biasing device for biasing the movable connector member, the first and second biasing devices including respective first and second coil springs which are disposed coaxially with each other.

(17) An electric-component mounting system according to the above mode (4), wherein the switch member of the valve switching device is stationary, and the directional control valve is movable by the nozzle elevating and lowering device, relative to the switching member, to cause the switching member to switch the directional control valve from the negative-pressure applying state to the atmospheric-pressure applying state.

(18) An electric-component mounting system according to the above mode (4), further comprising a substrate-holding device operable to hold a circuit substrate that has the component-mounting surface.

The circuit substrate may be a printed-wiring board, which is an electrically insulating board with a printed wiring, on which none or some of the required electric components have been mounted. The circuit substrate may be a substrate on which solder bumps are formed for package components protected by protective covering.

The substrate-holding device may include a substrate-supporting unit for supporting the circuit substrate, and a supporting-unit moving device for moving the substrate-supporting unit in a plane parallel to the component-mounting surface of the circuit substrate. Alternatively, the substrate-holding device may be a stationary device for holding the circuit substrate at a predetermined position.

The substrate-holding device is constructed according to the specific arrangement of a component-mounting device that includes at least one suction nozzle and is arranged to mount the electric components on the circuit substrate.

For instance, the component-mounting device may be one of: (a) a rotary type; (b) a two-axes linear type; and (c) a one-axis linear type. The component-mounting device of the rotary type includes a plurality of component-mounting units, and a turning device for turning the component-mounting units about a common axis of turning. Each of the component-mounting units includes a component-mounting head provided with a suction nozzle holder for holding the suction nozzle. The turning device is operated to turn the component-mounting units about the common axis, so that the component-mounting heads are sequentially moved to and stopped at a plurality of working positions, which includes a component-receiving position at which the suction nozzle receives the electric component from a component-supplying device, and a component-mounting position at which the electric component is transferred from the suction nozzle onto the component-mounting surface of the circuit substrate. The component-mounting device of the two-axes linear type includes at least one component-mounting unit each including a component-mounting head provided with a suction nozzle holder for holding the suction nozzle, and a two-axes positioning device which carries each component-mounting unit and is movable in an XY plane parallel to the component-mounting surface of the circuit substrate, so that the suction nozzle receives the electric component from the component-supplying device, and transfers the electric component onto the component-mounting surface. The XY plane is defined by mutually perpendicular X and Y axes that are perpendicular to the direction of movement of the suction nozzle by the nozzle elevating and lowering device. The component-mounting device of the one-axis linear type also includes at least one component-mounting unit, and a one-axis positioning device which carries each component-mounting unit and which is movable along one of the X and Y axes. The suction nozzle as well as the suction nozzle holder may be considered to be a part of the component-mounting head of the component-mounting unit.

In the component-mounting device of the rotary type, the turning device may include a rotary body which holds the component-mounting units and which is rotated in opposite directions to sequentially move the component-mounting heads at the component-receiving and component-mounting positions. Alternatively, the turning device may include an indexing body which holds the component-mounting units such that the component-mounting units are equiangularly arranged in the rotating direction of the indexing body. The indexing body is intermittently rotated to sequentially move the component-mounting heads to the component-receiving and component-mounting positions. Further alternatively, the turning device may include a plurality of turnable members which hold the respective component-mounting units and which are turnable about a common axis of turning. Each component-mounting unit is disposed on the corresponding turnable member such that the component-mounting unit is rotatable and axially movable. The turnable members are rotated by a circular-motion applying device including a cam device, so that the turnable members are moved to and stopped at respective working positions at different points of time, in a predetermined pattern of moving speed.

Where the electric-component mounting system uses the component-mounting device of the rotary type, the substrate-holding device includes the substrate-supporting unit and the supporting-unit moving device arranged to move the substrate-supporting unit in the XY plane parallel to the component-mounting surface of the circuit substrate. In this case, the component-supplying device provided to supply each suction nozzle with the electric component includes a component supply table carrying a plurality of component feeders, and a table positioning device arranged to move the component supply table in a direction in which component-supply portions of the component feeders are arranged. In the electric-component mounting system including the component-mounting device of the two-axes linear type, the substrate-holding device and the component-supply table are stationary. In the electric-component mounting system including the component-mounting device of the one-axis linear type including the one-axis positioning device movable in one of the X and Y axes, the substrate-holding device includes the substrate-supporting unit and the supporting-unit moving device which is arranged to move the substrate-supporting unit in the other of the X and Y axes. In this case, the component-supplying device may be fixedly provided such that the component-supply portions of the component feeders are located on a path of movement of the component-mounting unit or units. Alternatively, the component-supplying device is movable in a direction in which the component-supply portions are arranged on the component supply table.

The component-mounting device which holds each component-mounting unit and which is arranged to move the component-mounting unit along a circular or straight path in the XY plane may be given an additional movement or movements by another moving or positioning device. For example, the indexing body (e.g., intermittently rotating body) which holds a plurality of component-holding units and is rotatable to turn the component-holding units along a circular path may be mounted on an XY positioning device which is movable along the X and Y axes together with the indexing body. In this case, the component-mounting units (component-mounting heads) are moved to the predetermined component-mounting spots on the component-mounting surface of the circuit substrate, by a combination of a rotary motion of the indexing body and a movement of the XY positioning device in the XY plane. In this case, the axis of rotation of the indexing body may be either perpendicular or inclined with respect to the XY plane. Further, the vertical position at which the suction nozzle of the component-mounting unit receives the electric component from the component-supplying device may be different from the vertical position at which the electric component is transferred from the suction nozzle onto the component-mounting surface of the circuit substrate.

Where the component-mounting surface is a surface of a circuit substrate with a printed circuit on which the electric components are fixed by an adhesive agent or solder paste, a printed-circuit board is manufactured by an operation of the present electric-component mounting system. The adhesive agent or solder paste is applied to at least one of the electric component and the component-mounting surface. The present electric-component mounting system may be operated to perform a test operation to check the suction nozzle for a positioning error, in which reference electric components are mounted on a suitable test substrate.

### BRIEF DESCRIPTION OF THE DRAWINGS

The above and other objects, features, advantages and technical and industrial significance of the present invention will be better understood by reading the following detailed description of preferred embodiments of the invention, when considered in connection with the accompanying drawings, in which:

FIG. 1 is a plan view schematically showing an electronic-component mounting system constructed according to one embodiment of this invention;

FIG. 2 is a side elevational view partly in cross section showing a printed-wiring-board holding device of the electric-component mounting system;

FIG. 3 is a side elevational view partly in cross section showing a component-mounting device of the electronic-component mounting system;

FIG. 4 is a side elevational view partly in cross section showing a mounting head of the component-mounting device located at a component-receiving position of the electronic-component system, together with the corresponding head elevating and lowering device;

FIG. 5 is a side elevational view partly in cross section showing a mounting head of the component-mounting device located at a component-mounting position of the electronic-component mounting system, together with the corresponding head elevating and lowering device;

FIG. 6 is a front elevational view partly in cross section showing a suction nozzle held by the mounting head;

FIG. 7 is a side elevational view partly in cross section showing a directional control valve, a valve switching device and a positive-pressure applying device which are provided in the electronic-component mounting system;

FIG. 8 is a side elevational view partly in cross section showing the directional control valve, valve switching device and positive-pressure applying device of FIG. 7, which are placed in another operating state;

FIG. 9 is a block diagram showing elements of a control device of the electronic-component mounting system, which elements relate to the present invention;

FIG. 10 is a graph indicating a change in vertical position of a suction nozzle of the electronic-component mounting system, and a change in pressure applied to the suction nozzle, when an electronic component is mounted on a printed-wiring board by the suction nozzle;

FIG. 11 is a view for explaining a relative position of the suction nozzle, elevator member, directional control valve, valve switching devices and pressure applying device, in the vertical direction, when the electronic component is mounted on the printed-wiring board by the suction nozzle;

FIG. 12 is a view schematically showing directional control valves, valve switching deices and a positive-pressure applying device which are provided in an electronic-component mounting system constructed according to another embodiment of this invention; and

FIG. 13 is a plan view schematically showing an electronic-component mounting system according to a further embodiment of this invention.

### DETAILED DESCRIPTION OF THE PREFERRED EMBODIMENTS

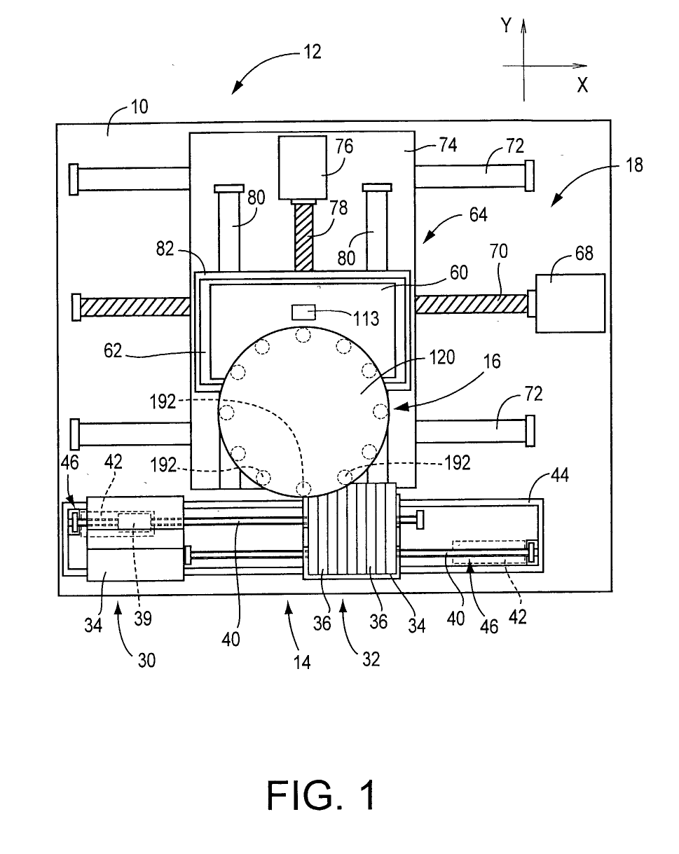

Referring first to FIG. 1, reference numeral 10 denotes a machine base of an electric-component mounting system in the form of an electronic-component mounting system 12. The electronic-component mounting system 12 includes a component-supplying device 14, a component-mounting device 16, and a circuit-substrate supporting device in the form of a printed-wiring board holding device 18 (hereinafter abbreviated as “PWB holding device 18”), which are mounted on the machine base 10. The electronic-component mounting system 12 and the component-mounting device 16 may be called an electronic-component placing system and an electronic-component placing device.

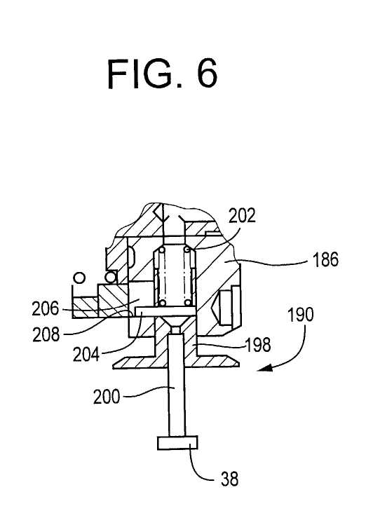

The component-supplying device 14 includes two component supply tables 30, 32. However, only one of these two component supply tables may be provided. Each of the two component supply tables 30, 32 includes a feeder support structure in the form of a feeder carriage 34, and a plurality of tape feeders 36 mounted on the feeder carriage 34. Each tape feeder 36 is arranged to feed a carrier tape (not shown) which accommodates electric components in the form of electronic components 38 (FIG. 6). The carrier tape includes a carrier substrate (not shown) which has a multiplicity of component-accommodating recesses formed at a suitable interval along the length of the tape. The electronic components 38 are accommodated in the respective component-accommodating recesses, and the opening of each recess is closed by a covering tape bonded to the carrier substrate. The carrier tape is fed by a tape feeding device (not shown) while the covering tape is removed from the carrier substrate, so that the electronic components 38 are successively fed to a predetermined position at a component-supply portion of the tape feeder 36. The plurality of tape feeders 36 are removably mounted on the feeder carriage 34 such that the component-supply portions of the tape feeders 36 are arranged along a predetermined line, for example, along a horizontal straight line. The present electronic-component mounting system 12 has an XY coordinate system defined by an X axis and a Y axis which are perpendicular to each other and which cooperate to define a horizontal XY plane. The direction in which the component-supply portions of the tape feeders 36 are arranged on the feeder carriage 34 is parallel to the X-axis direction (right and left direction as seen in FIG. 1).

The feeder carriage 34 of each component supply table 30, 32 has a ballnut 39 fixed thereto. The ballnut 39 is held in engagement with a feed screw in the form of a ballscrew 40, which is rotated by a carriage drive motor 42, so that each component supply table 30, 32 is moved in the X-axis direction while being guided by a guiding device including a guide rail 44. Thus, the component-supply portion of the plurality of tape feeders 36 are selectively brought into a predetermined component-supply position. The ballscrew 40 and the carriage drive motor 42 constitute a major portion of a table positioning device 46 operable to move each component supply table 30, 32. The two component supply tables 30, 32 are respectively moved by two table positioning devices 46. The guide rail 44 is used commonly for the two component supply tables 30, 32. The electric components 38 are supplied from the two component supply tables 30, 32 in a manner well known in the art, for instance, in a manner as disclosed in JP-B2-8-21791. In FIG. 1, the nut 39 of the component supply table 30 is shown, but the tape feeders 36 mounted on the table 30 are not shown, while the tape feeders 36 of the component supply table 32 are shown, but the nut 39 of the table 32 is not shown.

The PWB holding device 18 includes a substrate supporting unit in the form of a printed-wiring-board supporting unit 62 (hereinafter abbreviated as “PWB supporting unit”) arranged to support a circuit substrate in the form of a printed-wiring board 60, and a supporting-unit moving device 64 arranged to move the PWB supporting unit 62 for thereby moving the printed-wiring board 60.

The supporting-unit moving device 64 includes an X-axis slide 74, and a Y-axis slide 82 mounted on the X-axis slide 74. The X-axis slide 74 includes is moved in the X-axis direction by an X-axis drive motor 68 and a feedscrew in the form of a ballscrew 70, while being guided by a guiding device including a guide rail 72. The Y-axis slide 82 is moved in the Y-axis direction by a Y-axis drive motor 76 and a feedscrew in the form of a ballscrew 78, while being guided by a guiding device including a guide rail 80.

The Y-axis slide 82 is arranged to support the PWB supporting unit 62, which in turn is arranged to support the printed-wiring board 60 such that the board 60 maintains a horizontal attitude, that is, such that the board 60 has a component-mounting surface 84 parallel to the horizontal XY plane in which the board 60 is movable with the PWB supporting unit 62, to a desired position.

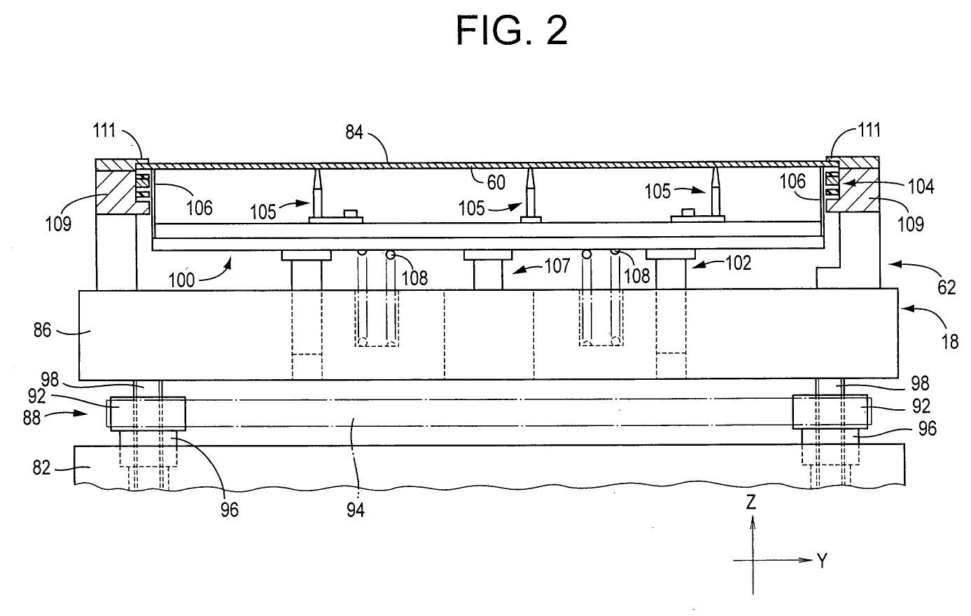

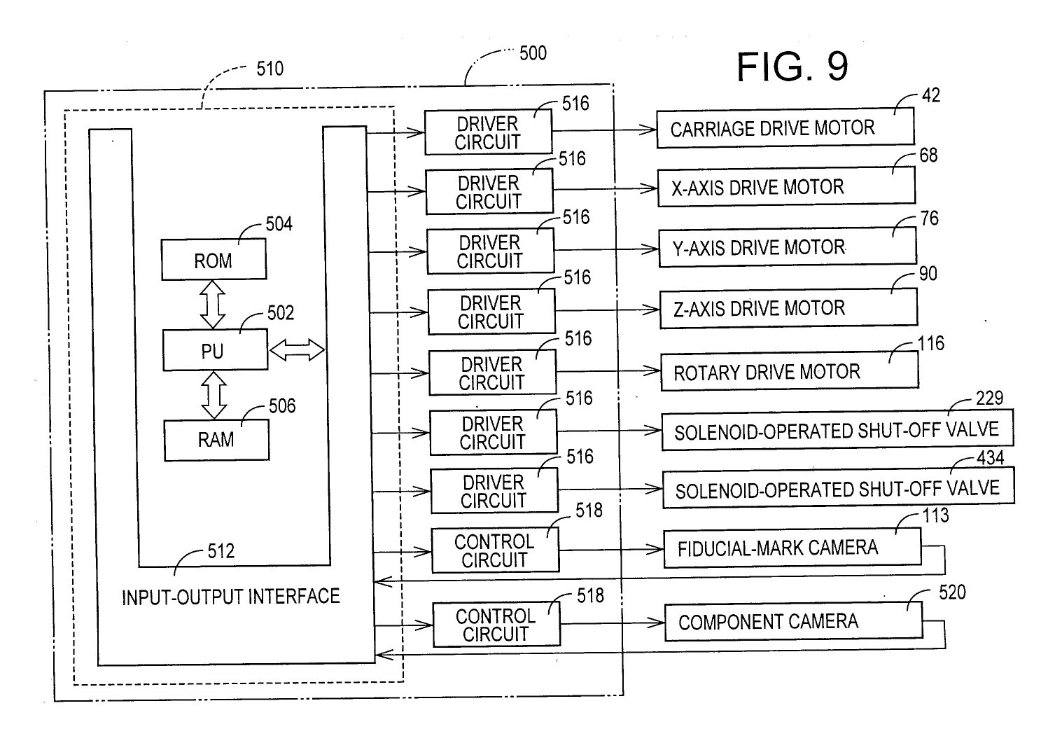

As shown in FIG. 2, a Z-axis slide 86 is mounted on the Y-axis slide 82, such that the Z-axis slide 86 is movable by a Z-axis positioning device 88 in a vertical or Z-axis direction perpendicular to the XY plane. The Z-axis positioning device 88 includes a drive source in the form of a Z-axis drive motor 90 (shown in FIG. 9). A plurality of ballnuts 96 are supported by the Y-axis slide 82 such that the ballnuts 96 are rotatable about their vertical axes relative to the Y-axis slide 82 but are not axially movable relative to the Y-axis slide 82. A rotary motion of the Z-axis drive motor 90 is transmitted to the ballnuts 96 through a plurality of timing pulleys 92 and a timing belt 94. The ballnuts 96 are held in engagement with respective feedscrews in the form of ballscrew 98 fixed to the Z-axis slide 86 so as to extend in the vertical direction. The Z-axis slide 86 is movable in the Z-axis direction when the ballnuts 96 are simultaneously rotated by the Z-axis drive motor 90. The Z-axis drive motor 90 is an electric motor, more precisely, a servomotor whose angle of rotation can be controlled with a relatively high degree of accuracy. The Z-axis slide 86 can be moved to a desired position in the vertical or Z-axis direction with high accuracy by controlling the Z-axis drive motor 90. The servomotor may be replaced by a stepping motor.

On the Z-axis slide 86, there are mounted a circuit-substrate supporting device in the form of a printed-wiring-board supporting device (PWB supporting device) 100, an elevating and lowering device 102 operable to vertically move the PWB supporting device 100, and a printed-wiring-board conveyor (PWB conveyor) 104 operable to feed the printed-wiring board 60. The PWB supporting device 100 is constructed as disclosed in JP-A-11-195899, for instance, and has a plurality of support members 105 and a pair of clamping members 106. As shown in FIG. 2, the elevating and lowering device 102 includes an air cylinder 107, and elastic members in the form of springs 108 serving as a biasing device. In the present embodiment, the Z-axis slide 86 and the PWB supporting device 100 cooperate to constitute the PWB supporting unit 62.

With a vertical movement of the Z-axis slide 86, the PWB supporting device 100 and the PWB conveyor 104 are moved in the Z-axis direction to a predetermined board-loading/unloading position at which the printed-wiring board 60 is moved by a board loading device (not shown) onto the PWB conveyor 104, and is moved from the PWB conveyor 104 onto a board unloading device (not shown). The PWB supporting device 100 is elevated by the elevating and lowering device 102 so that the printed-wiring board 60 placed on the PWB conveyor 104 is supported by the support members 105 of the PWB supporting device 100. The PWB conveyor 104 is provided with a pair of guide rails 109 which have respective retainer portions 111. The clamping members 106 cooperate with the retainer portions 111 to clamp the printed-wiring board 60.

When the electronic components 38 are mounted on the printed-wiring board 60, the Z-axis slide 86 is lowered to lower the printed-wiring board 60 from the above-indicated board-loading/unloading position down to a predetermined component-mounting position at which the PWB holding device 18 is positioned by the supporting-device moving device 64 in the XY plane, that is, in the horizontal plane parallel to the component-mounting surface 84 of the board 60, when each electronic component 38 is mounted at a predetermined spot on the component-mounting surface 84. Namely, the component-mounting surface 84 has a plurality of component-mounting spots at which the respective electronic components 38 are mounted, such that the component-mounting spots are sequentially located at a predetermined component-mounting position of the component-mounting device 16, by horizontal movements of the PWB holding device 18. While an operation to mount each electronic component 38 on the printed-wiring board 60 is performed with the board 60 located at the component-mounting position, the height of the board 60 (height of the component-mounting surface 84) is adjusted by a movement of the Z-axis slide 86 in the Z-axis direction, depending upon the height dimension of the electronic component 38.

Two fiducial marks (not shown) are provided on the component-mounting surface 84 of the printed-wiring board 60. Images of these fiducial marks on the board 60 as held by the PWB holding device 18 are taken by a fiducial mark camera 113, which is held stationary, as shown in FIG. 1. In the present embodiment, the fiducial mark camera 113 is a CCD camera including a matrix of CCDs (charge-coupled devices or elements) and a lens system. The CCD camera is capable of taking a two-dimensional image of an object at one time. An illuminating device is provided to illuminate the object (fiducial marks) and its vicinity when the image of the object is taken by the fiducial-mark camera 113.

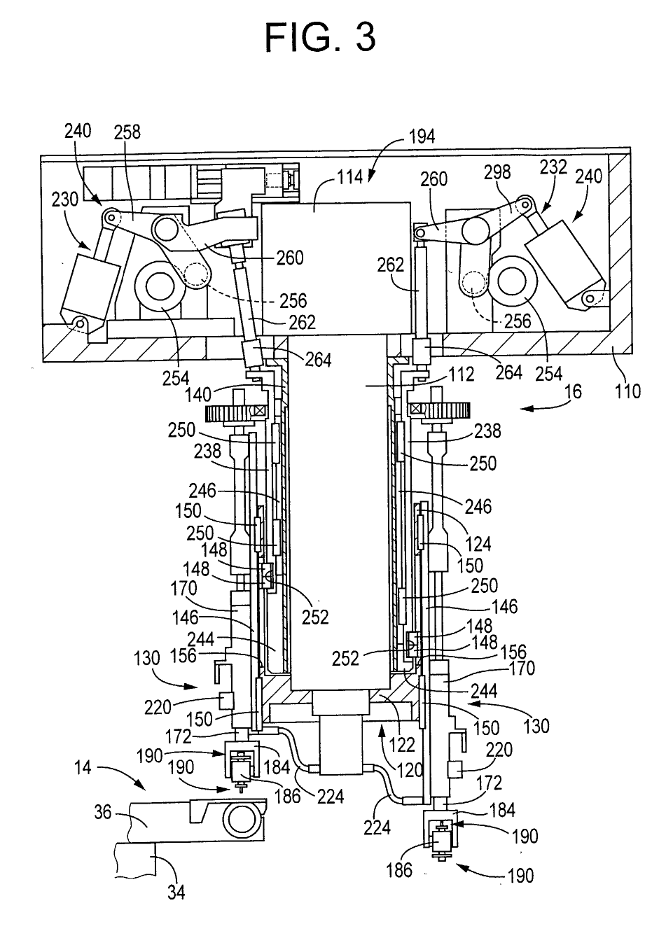

Referring next to FIGS. 3-5, there will be described the component-mounting device 16. The component-mounting device 16 is constructed as disclosed in JP-A-6-342998. In FIG. 3, reference sign 110 denotes a frame provided on the machine base 10. The frame 110 supports a rotary shaft 112 such that the rotary shaft 112 is rotatable about a vertical axis by a rotary drive device 114, which includes a roller gear and a roller-gear cam. When the roller-gear cam is rotated in one direction by a rotary drive motor 116 (shown in FIG. 9) at a predetermined constant speed, a plurality of rollers of the roller gear are sequentially brought into rolling engagement with a cam rib of the roller-gear cam, so that the rotary shaft 112 is intermittently rotated about the vertical axis, by a predetermined angle for each intermittent rotary motion.

A rotating member in the form of an indexing body 120 is fixed to the lower end portion of the rotary shaft 112 which extends downwardly from the frame 110. The indexing body 120 is a generally cylindrical member which is closed at one of its opposite axial ends and open at the other axial end. The indexing body 120 includes a bottom portion 122 at which the indexing body 120 is fixed to the rotary shaft 112, and a cylindrical portion 124 which extends from the bottom portion 122 toward the frame 110. The cylindrical portion 124 carries sixteen component-mounting units 130 equiangularly arranged in its circumferential direction. When the rotary shaft 112 is intermittently rotated by the rotary drive device 114, the indexing body 120 is intermittently rotated, by a predetermined angle equal to the angular spacing interval of the component-mounting units 130, for each intermittent rotary motion. Thus, the sixteen component-mounting units 130 are turned about a common vertical axis of turning, that is, about the axis of the indexing body 120, so that each component-mounting unit 130 is sequentially moved to and stopped at sixteen working stations or positions, which are arranged along a circular path of turning movement of each unit 130. The sixteen working positions include: a component-receiving position (component-holding or -sucking position); a component-hold-position detecting position (image-taking position); a component-hold-position rectifying position; a component-mounting position; and a suction-nozzle selecting position.

As shown in FIG. 3, a cylindrical cam 140 is fixed to the lower surface of the frame 110, such that the rotary shaft 112 extends through the cylindrical cam 140, with a suitable radial gap therebetween, and such that a lower portion of the cylindrical cam 140 is interposed between the cylindrical portion 124 of the indexing body 120 and the lower portion of the rotary shaft 112. The lower portion of the cylindrical cam 140 has a cam groove (not shown) open in its outer circumferential surface in which there are rotatably fitted a pair of rollers 148 attached to a guide rail 146 of each component-mounting unit 130.

The indexing body 120 has sixteen pairs of guide blocks 150 attached to its outer circumferential surface such that the pairs of guide blocks 150 are equiangularly spaced from each other in the circumferential direction of the indexing body 120. The sixteen guide rails 146 are vertically movably held in engagement with the respective pairs of guide blocks 150. These guide rails 146 and guide blocks 150 cooperate to constitute a guiding device for guiding the vertical movement of each component-mounting unit 130.

The two rollers 148 are attached to a longitudinally intermediate portion of the corresponding guide rail 146 such that each of the rollers 148 is rotatable about a horizontal axis perpendicular to the axis of rotation of the indexing body 120. The two rollers 148 extend through an elongate hole 156 formed through the cylindrical portion 124 of the indexing body 120, and are rotatably held in engagement with the cam groove of the cylindrical cam 140. The cam groove is formed such that its vertical position gradually changes in the circumferential direction of the cylindrical cam 140, so that each mounting head 130 is vertically moved with the corresponding pairs of rollers 148 in rolling contact with the upper and lower surfaces of the cam groove when each component-mounting unit 130 is turned with the intermittent rotary motion of the index body 120. In the present embodiment, the cam groove is formed so that the component-mounting unit 130 at the component-receiving position is located at its fully elevated position while the component-mounting unit 130 at the component-mounting position is located at its fully lowered position, and so that the component-mounting units 130 are moved (turned) in the horizontal direction between the component-receiving and component-mounting positions.

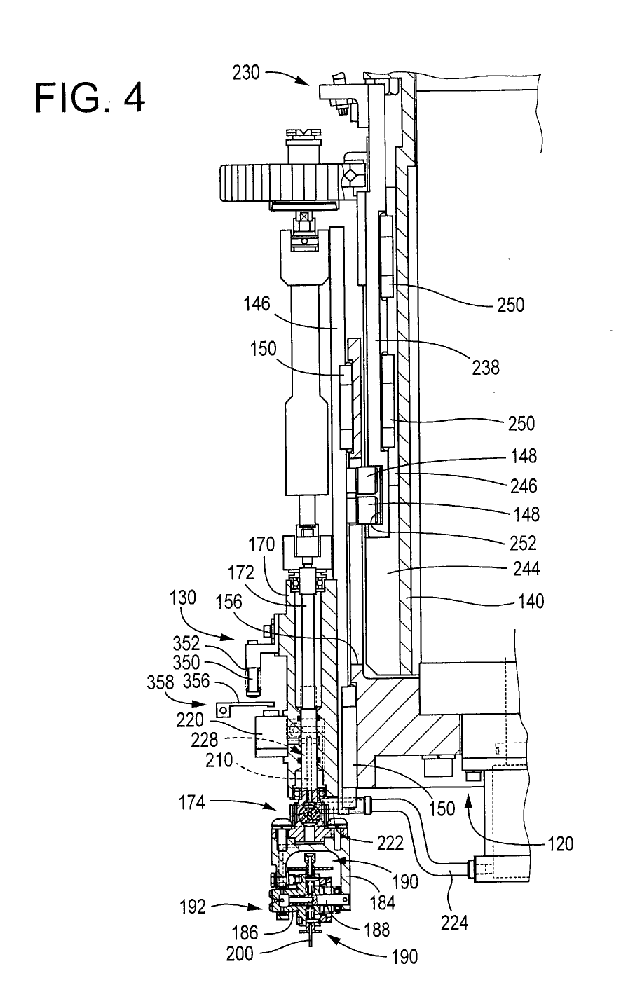

To each of the guide rails 146, there is fixed a sleeve 170 through which a rod 172 having a circular shape in transverse cross section extends, as shown in FIG. 4, such that the rod 172 is rotatable about its vertical axis (axis of rotation of a suction nozzle 190 which will be described) and such that the rod 172 is not axially movable relative to the sleeve 170.

As shown in FIG. 4, the lower end portion of the rod 172 extends downwards from the lower end of the sleeve 170, and a holder-mounting member 184 is fixed to the lower end of the rod 172. The holder-mounting member 184 has a support shaft 188 which extends in the horizontal direction perpendicular to the axis of rotation of the rod 172. A rotary holder 186 is mounted on the support shaft 188 such that the rotary holder 186 is rotatable about the horizontal axis. The holder-mounting member 184, rotary holder 186 and rod 172 cooperate to constitute a nozzle holder 174.

The rotary holder 186 is arranged to hold six suction nozzles 190 such that the suction nozzles 190 are equiangularly spaced apart from each other about the support shaft 188. To bring a selected one of the six suction nozzles 190 into an operating position, the rotary holder 186 is rotated about the support shaft 188 by a suction-nozzle selecting device (not shown) disposed at the suction-nozzle selecting position described above. The selected suction nozzle 190 placed in the operating position is coaxial with the vertically extending rod 172, and faces downwards, capable of holding the electronic component 38 by suction.

In the present embodiment, the selected suction nozzle 190 placed in the operating position and a portion of the nozzle holder 174 which holds the selected suction nozzle 190 cooperate to constitute a mounting head 192. The electronic-component mounting device 16 has a total of sixteen mounting heads 192, each which cooperates with the other five suction nozzles 190 to constitute the component-mounting unit 130. Only the above-indicated portion of the nozzle holder 174 which holds the selected suction nozzle 190 may be considered to be the mounting head 192. Alternatively, each of the six suction nozzles 190 and the corresponding portions of the nozzle holder 174 may be considered to constitute each mounting head 192. In this case, each component-mounting unit 130 has six mounting head 192. Further alternatively, the nozzle holder 174 and the six suction nozzles 190 held by the nozzle holder 174 cooperate to constitute the mounting head 192, which cooperates with the corresponding guide rail 146 to constitute the component-mounting unit 130. In this case, each component-mounting unit 130 has only one mounting head 192. In the following description, the electronic-component mounting system 12 is considered to have a total of 16 mounting heads 192.

With an intermittent rotary motion of the indexing body 120, the 16 mounting heads 192 are turned about the common axis of turning (about the axis of rotation of the indexing body 120), so that each mounting head 192 is sequentially moved to and stopped at each of the 16 working positions. In the present embodiment, the rotary shaft 112 and the rotary drive device 114 constitute an intermittently rotating device, which cooperates with the indexing body 120 to constitute a nozzle-moving device in the form of a nozzle rotating device 194. In FIG. 3, only two of the six suction nozzles 190 held by each component-mounting unit 130 are shown, in the interest of simplification. The component-supply portion of the component-supplying device 14 is located right below the suction nozzle 190 placed in the operating position of the mounting head 190 of the component-mounting unit 130 located at the component-receiving position. The component-supply portion of the tape feeder 36 from which the electronic component 38 is supplied is located at the component-supply position of the component-supplying device 14, that is, located right below the above-indicated suction nozzle 190.

Each of the suction nozzles 190 is arranged to hold the electronic component 38 by suction under a negative or reduced pressure. As shown in FIG. 6, each suction nozzle 190 has a nozzle body 198 and a suction tube 200 fixedly fitted in the nozzle body 198. Each suction nozzle 190 is held by the rotary holder 186 such that the suction nozzle 190 is not rotatable relative to the rotary holder 186 and is axially movable relative to the rotary holder 186. The suction nozzle 190 is biased by a spring 202 disposed between the rotary holder 186 and the suction nozzle 190, so that the suction nozzle 190 is normally held in its fully lowered or advanced position. To define the fully lowered position of the suction nozzle 190, a pin 204 is fixed to the suction nozzle 190 such that the pin 204 is perpendicular to the centerline of the suction nozzle 190, while an elongate hole 206 is formed in the rotary holder 186. The fully lowered or lowermost position of the suction nozzle 190 is determined by the free end of the pin 204 in contact with a lower end 208 of the elongate hole 206. In the present embodiment, the suction nozzles 190 held by the rotary holder 186 have different configurations, but the suction tubes 300 of the suction nozzles 190 have the same length, so that the lower or sucking end faces of all of the suction nozzles 190 lie on a circle concentric with the rotary holder 186.

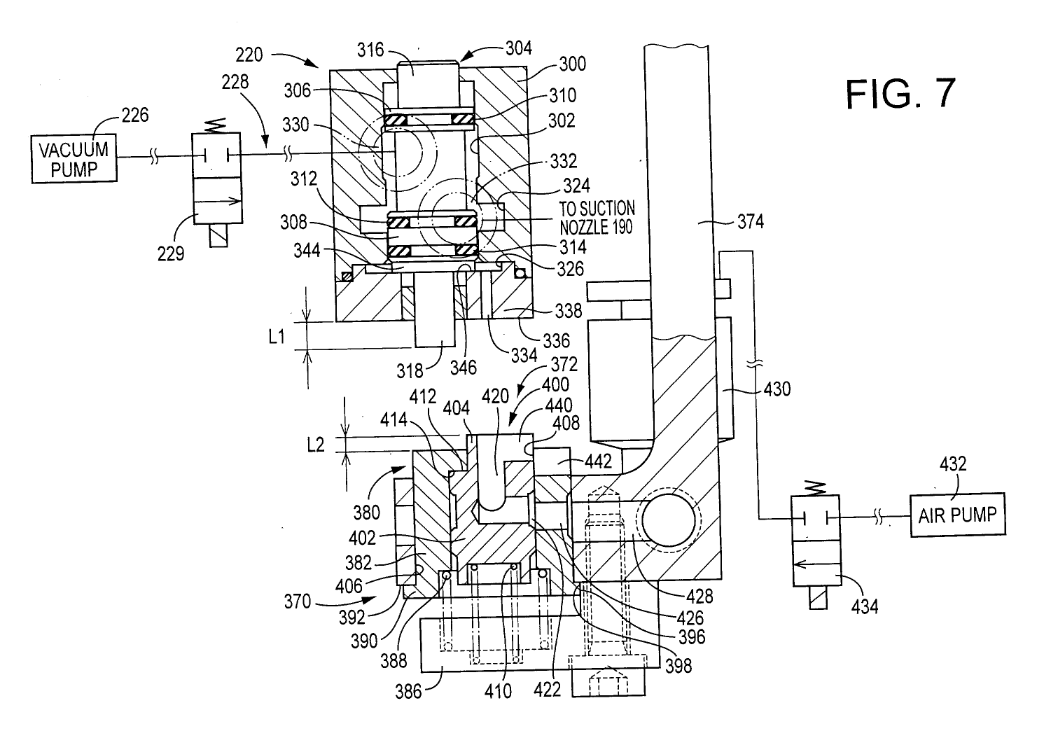

The selected suction nozzle 190 placed in the operating position is connected to a negative pressure source in the form of a vacuum pump 226 (shown in FIG. 7) through passages formed through the support shaft 188, rotary holder 186, holder-mounting member 184 and rod 172 (FIG. 4 showing only a passage 210 formed through the rod 172), a control valve in the form of a directional control valve 220 fixed to the sleeve 170, a connector member 222, a hose 224, passages formed through the indexing body 120 and rotary shaft 112, and a passage formed through the frame 110. Those passages including the passage 210 provide a connecting passage 228 for connecting the selected suction nozzle 190 to the vacuum pump 226. The connecting passage 228 is provided with the directional control valve 220, for connecting the selected suction nozzle 190 selectively to the vacuum pump 226 or the atmosphere. The construction and operation of the direction al control valve 220 will be described.

The rotary shaft 112 is fitted in the frame 110 so as to maintain fluid tightness at a portion of the connecting passage 228 between the rotary shaft 112 and the frame 110, even when the rotary shaft 112 is rotated relative to the frame 110. A solenoid-operated shut-off valve 229 is provided at a portion of the connecting passage 228 between the frame 110 and the vacuum pump 226, as shown in FIG. 7. This shut-off valve 229 is normally held in an open state permitting the application of a negative pressure from the vacuum pump 226 to the directional control valve 220. When the application of the negative pressure to the directional control valve 220 is not necessary, for example, when an operation of the electronic-component mounting system 12 to mount the electronic components 38 on the printed-wiring board 60 is stopped or interrupted, the solenoid-operated shut-off valve 229 is closed, to prevent an unnecessary operation of the vacuum pump 226. However, the solenoid-operated shut-off valve 229 is not essential and may be eliminated.

As shown in FIG. 3, two nozzle elevating and lowering devices in the form of two head elevating and lowering devices 230, 232 are disposed at respective two portions of the frame 110 and cylindrical cam 140, which correspond to the component-receiving and component-mounting positions, respectively. These head elevating and lowering devices 230, 232 constitute an axially moving device operable to vertically move the corresponding mounting heads 192 and the selected suction nozzles 190 located at the component-receiving and component-mounting positions.

The head elevating and lowering device 230 disposed at the component-receiving position will be described by reference to FIGS. 3 and 4. The head elevating and lowering device 230 includes a movable member in the form of an elevator member 238, and an elevator elevating and lowering device 240 for vertically moving the elevator member 238. The cylindrical cam 140 has a guide groove 244 open in a circumferential portion of its outer circumferential surface, which corresponds to the component-receiving portion. The guide groove 244 is formed so as to extend in the vertical direction. To the bottom surface of this guide groove 244, there is fixed a guide member in the form of an elongate guide rail 246 such that the guide rail 246 extends in the vertical direction, namely, in the axial direction of the corresponding suction nozzle 190 placed in the operating position and the indexing body 120. The elevator member 238 has two guide blocks 250 fixed thereto such that the guide blocks 250 are held in sliding engagement with the guide rail 246.

The elevator member 238 has a width almost equal to that of the guide groove 244 so that the elevator member 238 is closely fitted in the guide groove 244. The elevator member 238 has an engaging groove 252 formed in its lower end portion such that the engaging groove 252 extends in the horizontal direction and is open in the radially outward direction of the cylindrical cam 140. When the elevator member 238 is located at its fully elevated position, the engaging groove 252 is located at the same vertical position as the horizontal portion of the cam groove of the cylindrical cam 140, so that the engaging groove 252 functions as a cam groove continuous with the cam groove of the cylindrical cam 140.

The elevator elevating and lowering device 240 uses the rotary drive motor 116 as its drive source, and includes a motion converting device which includes a cam in the form of a rotary cam 254, a cam follower in the form of a roller 256 and levers 258, 260. A rotary motion of the rotary drive motor 116 is converted by the motion converting device into a vertical movement of a connecting rod 262, which is transmitted to the elevator member 238 through a spherical joint 264, so that the mounting head 192 disposed at the component-receiving position is vertically moved, whereby the selected suction nozzle 190 is vertically moved. The vertical movement of the suction nozzle 190 and the turning movement of the mounting head 192 take place in a predetermined timed relationship with each other, which is determined by the configuration of the rotary cam 254 and the cam used in the rotary drive device 114 for the rotary shaft 112. The vertical operating stroke of the elevator member 238 is adjustable in the head elevating and lowering device 230 at the component-receiving position.

However, the vertical operating stroke of the elevator member 238 in the head elevating and lowering device 232 at the component-mounting position is not adjustable and is held constant. That is, the fully lowered and fully elevated positions of the selected suction nozzle 190 at the component-mounting position are held constant. In the other aspects, the head elevating and lowering device 232 is identical with the head elevating and lowering device 230. The same reference signs as used for the head elevating and lowering device 230 are used for the head elevating and lowering device 232.

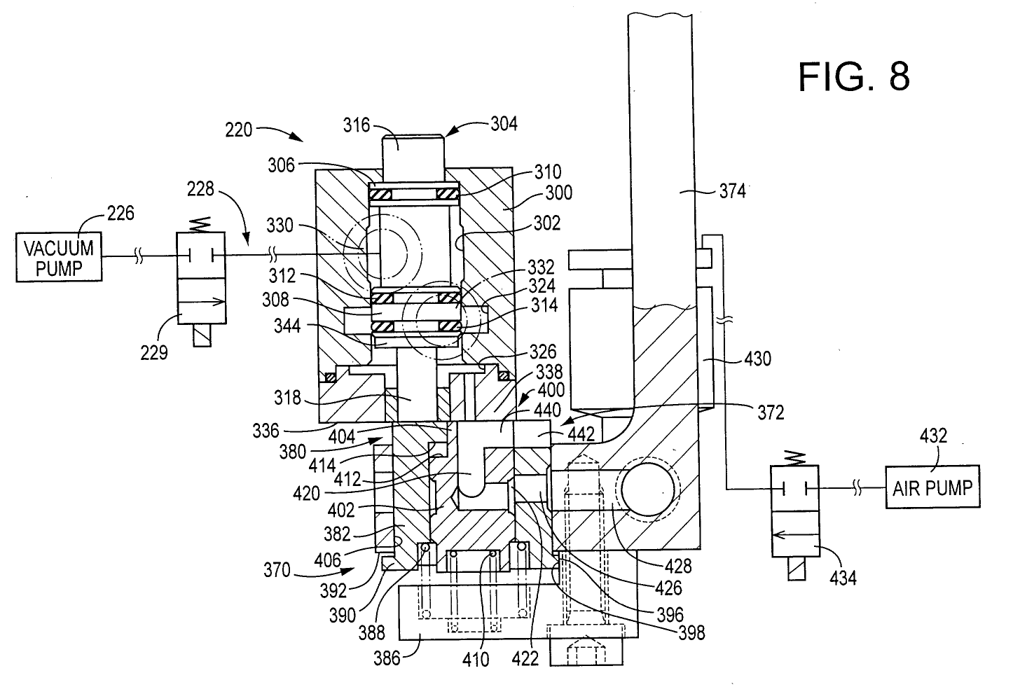

The directional control valve 220 will be described by reference to FIGS. 7 and 8. As shown in FIG. 7, the directional control valve 220 includes a housing 300 having a valve hole 302 formed therethrough so as to extend in a direction parallel to the axial direction of the selected suction nozzle 190 (in the vertical direction as seen in FIG. 7). A spool 304 is fitted in the valve hole 302 axially slidably relative to the housing 300, to selectively connect the connecting passage 228 to the vacuum pump 226 or the atmosphere. The vertically movable spool 304 has two lands 306, 308 spaced apart from each other in its axial direction (in the vertical direction). The upper land 306 is provided with an O-ring 310, while the lower land 308 is provided with two O-rings 312, 314 which are spaced apart from each other in the axial direction by a small distance. The spool 304 has opposite upper and lower end portions 316, 318 formed coaxially with each other and adjacent to the respective upper and lower lands 306, 308. These upper and lower end portions 316, 318 have a smaller diameter than an intermediate portion of the spool 304, and serve as operating portions.

The housing 300 has two annular grooves 324, 326 formed concentrically with the valve hole 302 and spaced apart from each other in the axial direction of the valve hole 302, in fluid communication with the valve hole 302. The housing 300 further has a negative-pressure port 330, a nozzle port 332 and a positive-pressure passage 334. The nozzle port 332 is open to the upper annular groove 324, and is held in communication with the selected suction nozzle 190 through the passages formed through the rod 172, etc. The negative-pressure port 330 is open to a portion of the valve hole 302 located between the upper annular groove 324 (communicating with the nozzle port 332) and the upper open end of the valve hole 302, and is connected to the vacuum pump 226 through the connector member 222, holes 224, and passages formed through the rotary shaft 112, etc. The positive-pressure passage 334 is formed radially outwardly of the valve hole 302, so as to extend in the axial direction of the valve hole 302, such that the positive-pressure passage 334 is open at its upper end to the lower annular groove 326, and at the lower end in a lower surface 336 of the housing 300, for exposure to the atmosphere.

The spool 304 has an annular stop portion 344 formed between the lower end portion (lower operating portion) 318 and the lower land 308, for abutting contact with a shoulder surface 346 of the housing 300 which partially defines the lower annular groove 326. The lowermost position of the spool 304 relative to the housing 300 is determined by the abutting contact of the stop portion 344 with the shoulder surface 346. When the spool 304 is placed in the lowermost position, the nozzle portion 332 is held in communication with the negative-pressure port 330 through the valve hole 302, and is disconnected from the positive-pressure passage 334 by the lower land 308 (O-ring 314), so that the directional control valve 220 is placed in a negative-pressure applying state in which the selected suction nozzle 190 is held in communication with the vacuum pump 226. In this negative-pressure applying state, the lower operating portion 318 of the spool 304 projects from the lower surface 336 of the housing 300 by a distance L1, as indicated in FIG. 7.

The spool 304 is movable to its uppermost position in which the lower end of the lower operating portion 318 is flush with the lower surface 336 of the housing 300. When the spool 304 is placed in this uppermost position, the nozzle port 332 is held in communication with the positive-pressure passage 334 through the upper and lower annular grooves 324, 326 and valve hole 302, and is disconnected from the negative-pressure port 330 by the lower land 308 (O-ring 312), so that the directional control valve 220 is placed in an atmospheric-pressure applying state in which the selected suction nozzle 190 is held in communication with the atmosphere. In this atmospheric-pressure applying state, the positive-pressure passage 334 is communicated with a portion of the connecting passage 228 between the spool 304 and the selected suction nozzle 190. A portion of the housing 300 in which the positive-pressure port 334 is formed constitutes a first connecting portion 338. In the atmospheric-pressure applying state, the upper operating portion 316 of the spool 304 projects from the upper end of the housing 300, as indicated in FIG. 8.

The O-rings 310, 312, 314 function as a sealing device to inhibit the application of a negative pressure to the selected suction nozzle 190 when the directional control valve 220 is placed in the atmospheric-pressure applying state with the spool 304 located at its uppermost position, and to prevent leakage of the negative pressure from the selected suction nozzle 190 when the directional control valve 220 is placed in the negative-pressure applying state with the spool 304 located at its lowermost position. The O-rings 310, 312, 314 also function as friction members or a holding device to hold the spool 304 at its uppermost and lowermost positions or hold the directional control valve 220 in its negative-pressure and atmospheric-pressure applying states, with a force of friction with the inner surface of the valve hole 302.

As shown in FIG. 4, the sleeve 170 is provided with a switching actuator in the form of a switching pin 350 for switching the directional control valve 220 to the negative-pressure applying state of FIG. 7. The switching pin 350 is supported by the sleeve 170 such that the switching pin 350 is movable in the axial direction of the sleeve 170 (in the vertical direction) relative to the sleeve 170, and is biased in the downward direction by an elastic member in the form of a spring 352 serving as a biasing device.

As also shown in FIG. 4, a switching member in the form of a switching lever 356 is fixed to a portion of the frame 110 which corresponds to the component-receiving position. The switching lever 356 is rotatable about a horizontally extending axis which is perpendicular to the common axis of turning of the component-mounting units 130 (mounting heads 192) and which is tangential with a circular path of turning of the mounting heads 192 (directional control valves 220), at the component-receiving position. The vertical position of the switching lever 356 is determined such that the switching lever 356 is located between the upper operating portion 316 of the spool 304 of the directional control valve 220 and the switching pin 350 of the mounting head 192 located at the component-receiving position (as a result of the intermittent rotary motion of the indexing body 120), when the component-mounting unit 130 is located at its uppermost position by the head elevating and lowering device 230. The switching lever 356 cooperates with the switching pin 350 to constitute a valve switching device 358.

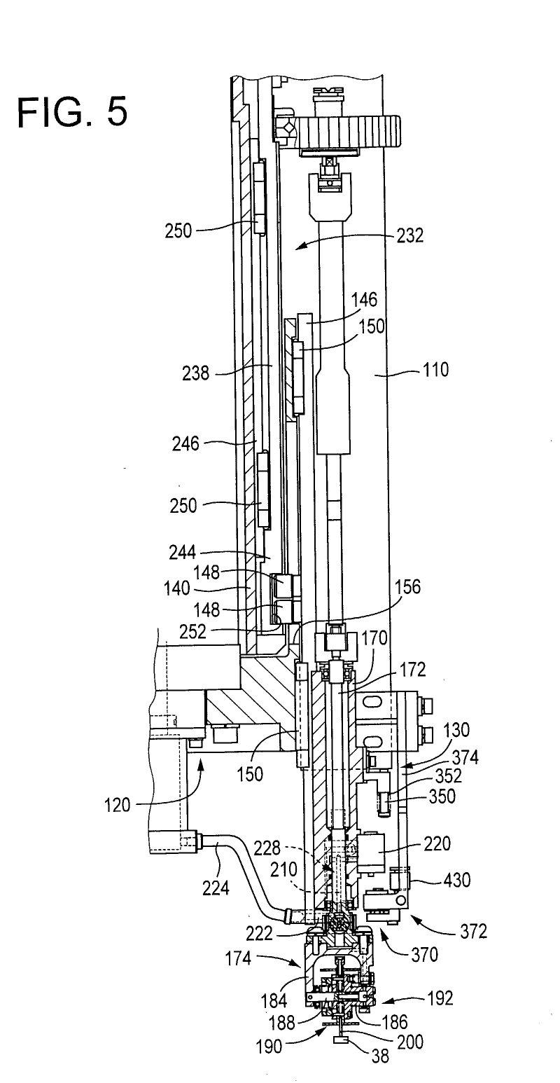

As shown in FIG. 5, a valve switching device 370 and a part of a positive-pressure applying device 372 are attached to a portion of the frame 110 which corresponds to the component-mounting position. The valve switching device 370 is arranged to switch the directional control valve 220 from the negative-pressure applying state of FIG. 7 to the atmospheric-pressure applying state (a positive-pressure applying state) of FIG. 8. The positive-pressure applying device 372 is arranged to apply a positive pressure to the selected suction nozzle 190. In FIG. 3, the valve switching device 370 and the positive-pressure applying device 372 are not shown. The valve switching device 370 is fixedly attached to the frame 110 by a downwardly extending bracket 374. The valve switching device 370 is located right below the directional control valve 220 of the component-mounting unit 130 located at the component-mounting position, when the component-mounting unit 130 is located at its uppermost position by the head elevating and lowering device 232. The directional control valve 220 carried by the sleeve 170 is moved relative to the stationary valve switching device 370 by the head elevating and lowering device 232, in the axial direction of the selected suction nozzle 190 (in the axial direction of the sleeve 170). Namely, the housing 300 of the directional control valve 220 is vertically movable relative to the bracket 374 which holds the valve switching device 370.

As shown in FIG. 7, a switching member 380 is held by a lower end portion of the bracket 374 such that the switching member 380 is movable relative to the bracket 374 in the vertical direction in which the selected suction nozzle 190 is movable by the head elevating and lowering device 232 and in which the directional control valve 220 is movable relative to the valve switching device 370. The switching member 380 includes a cylindrical hollow portion 382 that engages the lower end portion of the bracket 374, which serves as a holding member for holding the switching member 380. The switching member 380 is held by the bracket 374 such that the bore of the cylindrical hollow portion 382 is located outwardly of the spool 304 of the directional control valve 330 in the radial direction of the indexing body 120, that is, located radially outwardly of the circular path of turning of the mounting heads 192, so that a part of the upper annular end face of the cylindrical wall of the cylindrical hollow portion 382 is opposed to the lower end face of the lower end portion (lower operating portion) 318 of the spool 304, as is apparent from FIG. 7.

The switching member 380 is biased in the upward direction toward the spool 304 of the directional control valve 220 by an elastic member in the form of a compression coil spring 388 serving as a biasing device, which is disposed between the switching member 380 and a spring seat 386 attached to the bracket 374. The switching member 380 has a flange 390 formed at its lower end so as to extend the radially outward direction. The uppermost position of the switching member 380 relative to the bracket 374 is determined by abutting contact of the flange 390 with a lower surface 392 of the bracket 374. The flange 390 serving as a stop portion and the lower surface 392 serving as a stop surface cooperate with each other to constitute a stop device.

The flange 390 has a cutout providing a vertical straight abutting surface 396 for abutting contact with a vertical straight abutting surface 398 formed on the spring seat 386, so that the switching member 380 is positioned in its circumferential direction, that is, held at a predetermined angular position relative to the bracket 374. It will be understood that the abutting surfaces 396, 398 cooperate to constitute an angular positioning device for positioning the switching member 380 in the circumferential direction relative to the bracket 374.

A movable connector member 400 is concentrically fitted within the cylindrical hollow portion 382 of the switching member 380 such that the movable connector member 400 is movable relative to the switching member 380 in the axial direction of the cylindrical hollow portion 382 (in the axial direction of the selected suction nozzle 190). This movable connector member 400 serves as a second connecting portion. The movable connector member 400 is supported by the bracket 374 through the switching member 380 such that the movable connector member 400 is movable relative the bracket 374 in the axial direction in which the switching member 380 is movable relative to the directional control valve 220. The movable connector member 400 is a stepped cylindrical member including a large-diameter fitting portion 402 and a small-diameter connecting portion 404 which has a smaller diameter than the fitting portion 402 and which is eccentric with respect to the fitting portion 402.

The cylindrical hollow portion 382 of the switching member 380 has a stepped bore consisting of a large-diameter portion 406 concentric with the outer circumferential surface of the switching member 380, and a small-diameter portion 408 which has a smaller diameter than the large-diameter portion 406 and which is eccentric with respect to the large-diameter portion 406. The fitting portion 402 of the movable connector member 400 is fitted in the large-diameter portion 406, while the connecting portion 404 is fitted in the small-diameter portion 408.

As described above, the axis of the switching member 380 is located outwardly of the spool 304 of the directional control valve 220 in the radial direction of the indexing body 120. When the switching member 380 is positioned in the circumferential direction by the abutting contact of its abutting surface 396 with the abutting surface 398 of the spring seat 386, the small-diameter portion 408 of the bore of the cylindrical hollow portion 382 is located outwardly of the spool 304 of the directional control valve 220 in the radial direction of the indexing body 120, so that the connecting portion 404 of the movable connector member 400 is offset from the spool 304 in the radial direction of the spool 304, and is aligned with or opposed to the first connecting portion 338 in which the positive-pressure passage 334 is formed. Since the connecting portion 404 is fitted in the small-diameter portion 408 eccentric with the large-diameter portion 406, the movable connector member 400 is prevented from being rotated relative to the switching member 380 and the bracket 374. That is, the movable connector member 400 is held at a predetermined angular position in its circumferential direction relative to the switching member 380 and the bracket 374, by the engagement of the connecting portion 404 with the small-diameter portion 404. It will be understood that the connecting portion 404 and a portion of the switching member 380 which has the small-diameter portion 408 cooperate to constitute an angular positioning device for positioning the movable connector member 400 relative to the switching member 380.

The movable connector member 400 is biased in the upward direction toward the first connecting portion 338, by an elastic member in the form of a compression coil spring 410 serving as a biasing device, which is disposed between the movable connector member 400 and the spring seat 386. The coil spring 410 is disposed within and coaxially with the coil spring 388 provided to bias the switching member 3980.

The movable connector member 400 has a shoulder surface 412 formed between its fitting and connecting portions 402, 404, while the cylindrical hollow portion 382 of the switching member 380 has a shoulder surface 414 formed between its large-diameter and small-diameter portions 406, 408. The fully advanced or uppermost position of the movable connector member 410 biased by the spring 410 is determined by abutting contact of the shoulder surface 412 with the shoulder surface 414. In the uppermost position of the movable connector member 400, the connecting portion 404 projects from the upper end face of the switching member 380 toward the directional control valve 220. It will be understood that the shoulder surfaces 412 and 414 provide a stopper device for defining the fully advanced or uppermost position of the movable connector member 400.

The movable connector member 400 has a positive-pressure passage 420 which is open in the upper end face of the connecting portion 404 and in the outer circumferential surface of the fitting portion 402. The movable connector member 400 further has an annular passage 422 formed in the outer circumferential surface of the fitting portion 402, in communication with the positive-pressure passage 420. Since the connecting portion 404 is opposed to the first connecting portion 338 of the directional control valve 220, the open end of the positive-pressure passage 420 open in the upper end face of the connecting portion 404 is aligned with the positive-pressure passage 334 of the directional control valve 220. The passages 420, 422 are connected to a positive pressure source in the form of an air pump 432 through a passage 426 formed through the switching member 380, a passage 428 formed through the bracket 374, and a connector member 420. The passage 426 is held in communication with the passage 428, with the switching member 380 positioned relative to the bracket 374 in the circumferential direction as described above. A solenoid-operated control valve in the form of a solenoid-operated shut-off valve 434 is provided between the air pump 432 and the connector member 430. This shut-off valve 434 is a normally closed valve for selectively connecting and disconnecting the air pump 432 to and from the positive-pressure passage 420. However, the shut-off valve 434 is not essential, and may be eliminated.

The connecting portion 404 of the movable connector member 400 further has a groove 440 formed so as to extend in its radial direction and in communication with the positive-pressure passage 420. The groove 440 is U-shaped in cross section and is open in the upper end face and the outer circumferential surface of the connecting portion 404. The cylindrical wall of the cylindrical hollow portion 382 of the switching member 380 has a groove 442 formed therethrough for communication with the groove 440. The groove 442 is also U-shaped in cross section, slightly larger with than the groove 440, and open in the upper end face of the switching member 380. The groove 442 holds the groove 440 exposed to the atmosphere when the movable connector member 400 is located at its lowermost position in which the upper end face is flush with the upper end face of the switching member 380.

The present electronic-component mounting system 12 has a control device 500 shown in FIG. 500. The control device 500 is principally constituted by a computer 510 incorporating a processing unit (PU) 502, a read-only memory (ROM) 504, a random-access memory (RAM) 506, and a bus interconnecting the PU 502, ROM 504 and RAM 506. To the bus, there is connected an input-output interface 512 to which various sensors are connected.

To the input-output interface 512, there are also connected through driver circuits 516 various actuators such as the motors 42, 68, 76, 90, 116, all of which are servomotors in the present embodiment. Those motors are controlled on the basis of output signals of rotary encoders provided to detect the angular positions of the motors.

To the input-output interface 512, there are also connected through control circuits 158 the above-indicated fiducial-mark camera 113, the above-indicated solenoid-operated shut-off valves 229, 432, and a component camera 520. The component camera 520, which is disposed at the component-hold-position detecting position, is a CCD camera having a matrix of CCDs and a lens system. Like the fiducial-mark camera 113, the component camera 520 is capable of taking a two-dimensional image of the object (electronic component 38). The control device 500 includes the driver circuits 516 and control circuits 518 as well as the computer 510. The RAM 506 is used to store various control programs such as an electronic-component mounting control program for controlling an operation of the electronic-component mounting system 12 to mount the electronic components 38 on the printed-wiring board 60.

Then, there will be described the electronic-component mounting operation of the electronic-component mounting system 12 to mount the electronic components 38 on the printed-wiring board 60. Initially, the board 60 is loaded by the board loading device onto the PWB holding device 18, and supported by the PWB supporting unit 62. In this state, images of the fiducial marks provided on the board 60 are taken by the fiducial-mark camera 113, and X-axis and Y-axis positioning errors of the board 60 in the XY plane parallel to the component-mounting surface 84 are obtained on the basis of image data representative of the taken images of the fiducial marks. On the basis of the thus obtained positioning errors of the board 60, X-axis and Y-axis positioning errors ΔXP and ΔYP of each component-mounting spot on the board 60 are calculated.

After the X-axis and Y-axis positioning errors ΔXP and ΔYP of each component-mounting spot on the board 60 are calculated, an operation of the component-mounting device 16 to mount the electronic components 38 on the printed-wiring board 60 is initiated. In this operation, the indexing body 120 is intermittently rotated to sequentially move the 16 mounting heads 192 to the component-receiving position and other working positions. Operations of the 16 mounting heads 192 and operations of the other devices such as detecting devices at the appropriate working stations are performed concurrently with each other. The following description refers to the operations relating to one of the mounting heads 192 at each working station.

When the mounting head 192 is located at the component-receiving position, the selected suction nozzle 190 is lowered by the head elevating and lowering device 230. A downward movement of the elevator member 238 is initiated when the roller 148 is brought into engagement with the engaging groove 252 formed in the elevator member 238. As a result, the selected suction nozzle 190 is lowered with the mounting head 192.

The directional control valve 220 is lowered with the selected suction nozzle 190. Before the mounting head 192 (component-mounting unit 130) has reached the component-receiving position by rotation of the indexing body 120, the directional control valve 220 is held in the atmospheric-pressure applying state with the spool 304 placed in the uppermost position. While the elevator member 238 is lowered, the switching pin 350 comes into abutting contact with the switching lever 356, causing a pivotal motion of the switching lever 356. A point of abutting contact of the switching pin 350 with the switching lever 356, that is, a lever ratio of the switch lever 356 is determined such that a distance of downward movement of the free end of the switching lever 356 is larger than a distance of downward movement of the switching pin 350 with the elevator member 238. Accordingly, the free end of the switching lever 356 comes into abutting contact with the upper end face of the upper operating portion 316 of the spool 304 of the directional control valve 220, during the downward movement of the elevator member 238 (selected suction nozzle 190), so that the spool 304 is lowered to its lowermost position, whereby the directional control valve 220 is switched from the atmospheric-pressure applying state to the negative-pressure applying state of FIG. 7. As a result, the electronic component 38 is picked up by the suction nozzle 190 by suction under the negative pressure. The solenoid-operated shut-off valve 229 is held open during the electronic-component mounting operation, so that the negative pressure is applied from the vacuum pump 226 to the selected suction nozzle 190 when the directional control valve 220 is switched to the negative-pressure applying state.

The elevator member 238 is further lowered even after the spool 304 is lowered to the lowermost position by the switching lever 356. This downward movement of the elevator member 238 is permitted by a movement of the switching pin 350 relative to the sleeve 170 against a biasing force of the spring 352. The spool 304 is held in the lowermost position under the biasing action of the spring 352, to hold the directional control valve 220 in the negative-pressure applying state.

After the electronic component 38 has been held by the suction nozzle 190, the elevator member 238 is elevated to elevate the suction nozzle 190, and the mounting head 192 is moved to the next working position, so that the switching pin 350 is disengaged from the switching lever 356, with a result of a pivotal movement of the switching lever 356 back to its original position under a biasing action of a spring (not shown). In this state, the spool 304 is held in the lowermost position with the O-rings 310-314 held in frictional contact with the inner circumferential surface of the valve hole 302, to hold the directional control valve 220 in the negative-pressure applying state. The switching lever 356 now placed in the original position is ready to be pivoted by the switching pin 350 of the next component-mounting unit 130, to lower the spool 304 of the corresponding directional control valve 220.

When the suction nozzle 190 of the mounting head 192 in question is moved to the component-hold-position detecting position by an intermittent rotary motion of the indexing body 120, an image of the electronic component 38 held by this suction nozzle 190 is taken by the component camera 520.

Image data representative of the image of the electronic component 38 are processed to calculate hold position errors of the electronic component 38, by comparing the obtained image data with image data representative of the nominal position of the electronic component 38 as held by the suction nozzle 190. The hold position errors consist of center position errors ΔXE and ΔYE in the XY plane, and an angular positioning error Δθ of the electronic component 38. The center positions errors ΔXE and ΔYE are positioning errors of the center of the electronic component 38 in the XY plane with respect to the axis of rotation of the selected suction nozzle 190 in the X-axis and Y-axis directions, while the angular positioning error Δθ is a positioning error of the electronic component 38 in the circumferential direction of the selected suction nozzle 190.

Then, the mounting head 192 is moved to the component-hold-position rectifying position at which the angular position of the electronic component 38 is adjusted to eliminate the angular positioning error Δθ, with the mounting head 192 being rotated to rotate the electronic component 38 with the selected suction nozzle 190, by a component-hold-position rectifying device disposed at the component-hold-position rectifying position.

When the mounting head 192 has reached the component-mounting position, the selected suction nozzle 190 is lowered by the head elevating and lowering device 232, to lower the electronic component 38 and place it onto the component-mounting surface 84 of the printed-wiring board 60. At this time, the board 60 is positioned to bring the corresponding component-mounting spot into alignment with the component-mounting position of the component-mounting device 16. Movement data used to position the board 60 at this time are adjusted so as to eliminate the obtained X-axis and Y-axis positioning errors ΔXP and ΔYP of the board 60, the center position errors ΔXE and ΔYE of the electronic component 38, and center position errors of the electronic component 38 which take place due to the rotation of the electronic component 38 at the component-hold-position rectifying position to eliminate the angular positioning error Δθ. With the board 60 positioned according to the thus adjusted movement data, the electronic component 38 can be mounted at the corresponding nominal component-mounting spot with high positioning accuracy.

The electronic component 38 is lowered by the elevator member 238, into abutting contact with the component-mounting surface 84 of the board 60, before the elevator member 238 has been lowered to its lowermost position. A downward movement of the elevator member 38 after the contact of the electronic component 38 with the component-mounting surface 84 is permitted by a movement of the suction nozzle 190 relative to the nozzle holder 174 against a biasing force of the spring 202 whose compression reduces an abutting impact of the electronic component 38 against the board 60.

If the vertical position of the board 60 were held constant irrespective of the height dimension of the electronic components 38, the amount of compression of the spring 202 would vary with a change in the height dimension of the electronic components 38 of different kinds. To assure a constant biasing force produced by the spring 202 irrespective of the height dimension of the electronic components 38, the vertical position of the board 60 is adjusted depending upon the specific height dimension of the electronic component 38, while the lowermost position of the elevator member 232 (selected suction nozzle 190) is held constant. This adjustment of the vertical position of the board 60 permits the electronic component 38 to contact the component-mounting surface 84 of the board 60, when the selected suction nozzle 190 has been lowered to a predetermined constant vertical position. Accordingly, the amount of compression of the spring 202 is held constant irrespective of the height dimension of the electronic component 38. The amount of compression of the spring 202 is equal to a distance Ls of movement of the suction nozzle 190 relative to the nozzle holder 174 after the abutting contact of the electronic component 38 with the component-mounting surface 84. Accordingly, the electronic component 38 is pressed onto the component-mounting surface 84 with a predetermined constant force.

The directional control valve 220 is switched from the negative-pressure applying state to the atmospheric-pressure applying state as the selected suction nozzle 190 is lowered toward its lowermost position. When the downward movement of the selected suction nozzle 190 by the head elevating and lowering device 232 at the component-mounting position is initiated,, the directional control valve 220 is placed in its negative-pressure applying state of FIG. 7 with the spool 304 placed in its lowermost position, and the lower operating portion 318 of the spool 304 projects downwards from the lower end face of the housing 300 by a distance L1.

The directional control valve 220 fixed to the sleeve 170 is lowered toward the valve switching device 370 as the selected suction nozzle 190 is lowered with the elevator member 238. That is, the housing 300 is lowered relative to the stationary bracket 374 when the elevator member 238 is lowered. When the downward movement of the directional control valve 220 is initiated, the switching member 380 and the movable connector member 400 of the valve switching device 370 are both held at their uppermost positions of FIG. 7 under biasing actions of the springs 388, 410, in which the upper part of the connecting portion 404 of the movable connector member 400 projects from the switching member 380, in the upward direction toward the directional control valve 220 by a distance L2, as indicated in FIG. 7. This distance L2 of projection of the connecting portion 404 is smaller than the distance L1 of projection of the spool 304, and is larger than the distance Ls of movement Ls of the suction nozzle 190 relative to the nozzle holder 174. Since the connecting portion 404 of the movable connector member 400 is radially offset from the spool 304, the lower operating portion 318 of the spool 304 first comes into abutting contact with the switching member 380 during the downward movement of the directional control valve 220. Upon contacting of the lower operating portion 318 with the upper end face of the switching member 380, the movable connecting member 400 is spaced from the lower operating portion 318 in the radial direction, and is spaced from the housing 300 in the axial direction since the distance L2 of projection of the connecting portion 404 is smaller than the distance L1 of projection of the lower operating portion 318 from the housing 300.

When the elevator member 238 is further lowered, the spool 304 is pushed upwards by the switching member 380 and forced into the housing 300 against the force of friction between the O-rings 310-314 and the inner circumferential surface of the valve hole 302. Namely, the biasing force of the spring 388 biasing the switching member 380 in the upward direction is larger than the above-indicated force of friction, so that the spool 304 is forced by the switching member 380 into the housing 300. With this movement of the spool 304 relative to the housing 300, the switching action of the directional control valve 220 from the negative-pressure applying state to the atmospheric-pressure applying state is initiated.

During the movement of the spool 304 into the housing 300 of the directional control valve 220, the lower surface 336 of the housing 300 is brought into abutting contact with the upper end face of the connecting portion 338 of the movable connector member 400, the positive pressure passages 334, 420 are brought into communication with each other. The elevator member 238 is further lowered, and the spool 304 is further moved by the switching member 380 into the housing 300, while at the same time the movable connecting member 400 is moved downwards by the housing 300 from the uppermost position into the switching member 380, against a biasing force of the spring 410.

The directional control valve 220 is lowered until the elevator member 238 has reached the lowermost position. The lower surface 336 of the housing 300 comes into abutting contact with the upper end face of the switching member 380 when the elevator member 238 has been lowered to a L3 position which is located above the lowermost position by a distance L3. At this L3 position of the elevator member 238, the upper end face of the movable connector member 400 is flush with the upper end face of the switching member 380. A downward movement of the elevator member 238 from the L3 position to the lowermost position causes the switching member 380 to be lowered against the biasing force of the spring 388, and causes the movable connector member 400 to be lowered against the biasing force of the spring 410. At the lowermost position of the elevator member 238, therefore, the switching member 380 is held forced at its upper end face against the lower surface 336 of the housing 300 under the biasing action of the spring 388, with the lower end face of the spool 304 being held flush with the lower surface 336, while the movable connector member 400 is held forced at its upper end face against the lower surface 336 under the biasing force of the spring 410. Accordingly, the directional control valve 220 is switched to the atmospheric-pressure applying state, so that the suction of the electronic component 38 onto the suction nozzle 190 under the negative pressure is released.

The above-indicated distance L3 between the L3 position and the lowermost position of the elevator member 238 is smaller than the above-indicated distance L2 and the above-indicated distance Ls. The spool 304 can be moved from its lowermost position of FIG. 7 to its uppermost position of FIG. 8 to permit the switching member 380 to contact the lower surface 336 of the housing 300, an axial distance of the directional control valve 220 from the land 306 to a shoulder surface formed near the upper end of the valve hole 302 is made larger than the distance L1 of projection of the spool 304.

As described above, the selected suction nozzle 190 of the mounting head 192 at the component-mounting position is lowed to place the electronic component 38 on the printed-wiring board 60, and to switch the directional control valve 220 from the negative-pressure applying state to the atmospheric-pressure applying state. At this time, the solenoid-operated shut-off valve 434 provided between the air pump 432 and the switching member 380 is opened to permit a positive pressure, that is, a compressed air to be applied from the air pump 432 to the suction nozzle 190 through the directional control valve 220 placed in the atmospheric-pressure applying state, namely, through the positive-pressure passages 420, 334 held in communication with each other, the nozzle port 332, and the passages including the passage 210. As a result, the electronic component 38 is released from the suction nozzle 190.

The positive-pressure passage 420 formed through the movable connector member 400 is exposed to the atmosphere through the groove 440 also formed in the movable connector member 400 while the movable connector member 400 is placed in its uppermost position of FIG. 7 with its connecting portion 404 projecting upwards from the switching member 380. While the movable connector member 400 is placed in its lowermost position of FIG. 8 and accommodated within the switching member 380, the positive-pressure passage 420 is exposed to the atmosphere through the groove 440 and the groove 442 formed through the switching member 380. Accordingly, the positive pressure applied to the positive-pressure passage 420 partly leaks into the atmosphere, so that the compressed air is fed to the suction nozzle 190 at a suitable rate of flow, while preventing the electronic component 38 from being displaced or dislocated on the printed-wiring board 60, due to an air flow toward the electronic component 38 already placed on the board 60.

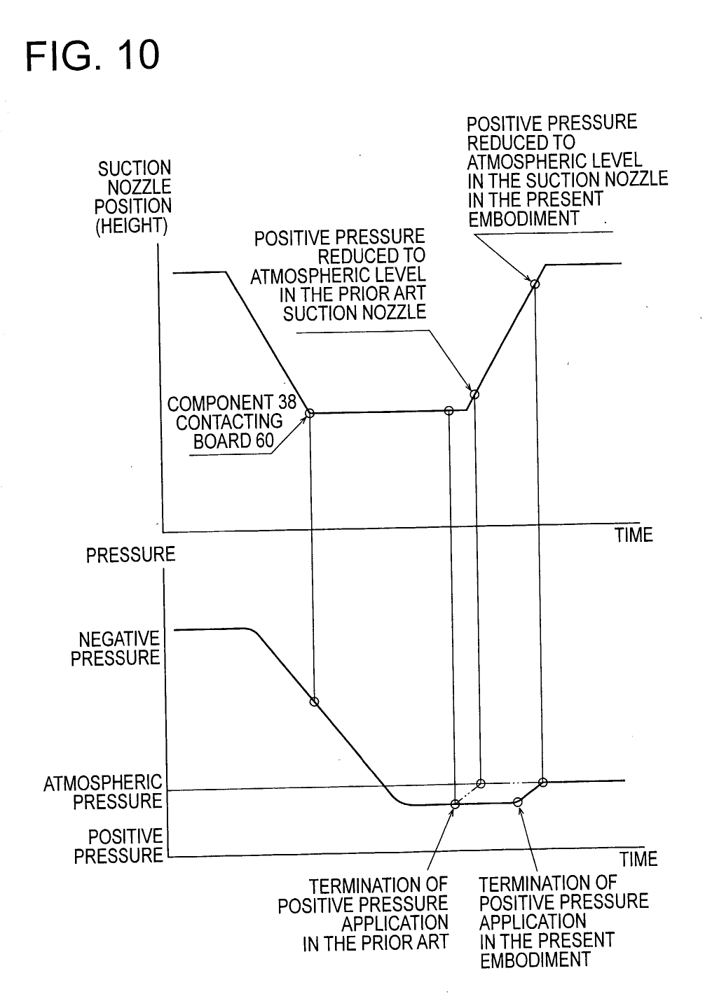

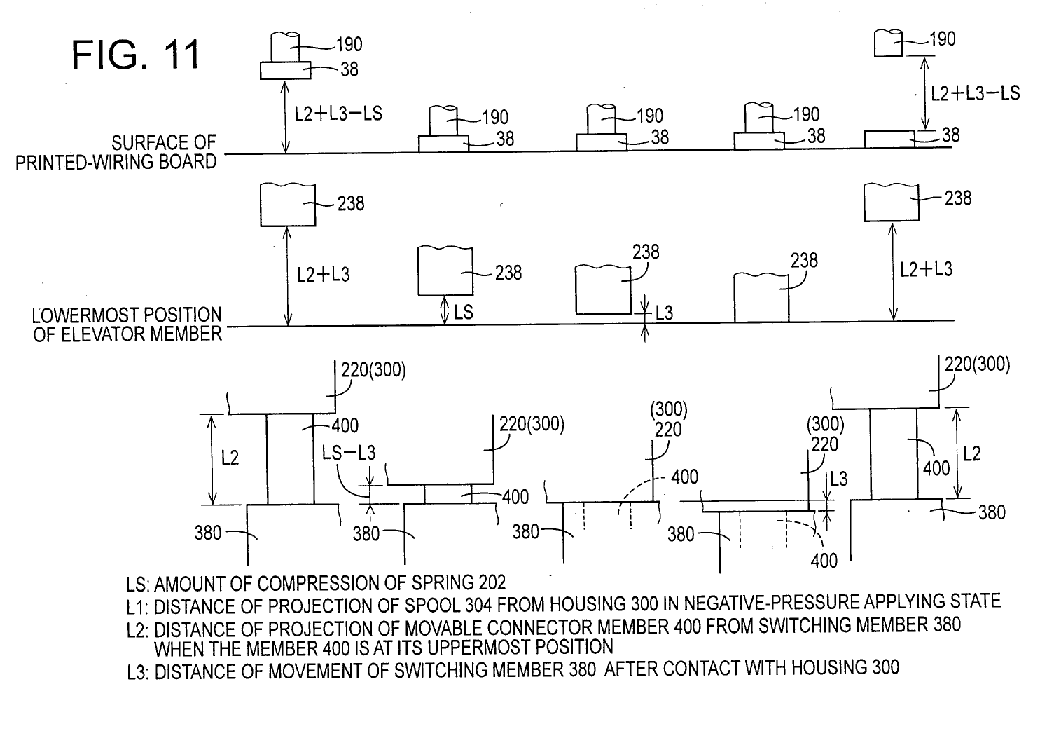

Referring to FIG. 10, there are indicated chronological changes in the vertical position of the selected suction nozzle 190 and in the pressure applied thereto during the downward and upward movements of the elevator member 238. A reference is further made to FIG. 11, which indicates relationships in the vertical position among the selected suction nozzle 190, elevator member 238, directional control valve 220, switching member 380 and movable connector member 400. The relationships indicated in FIGS. 10 and 11 were obtained by experimentation in which a change in the pressure applied to the suction nozzle 190 was detected by a pressure sensor (not shown) during a test operation wherein the selected suction nozzle 190 was lowered and elevated with the elevator member 238 by the head elevating and lowering device 232, to place the electronic component 38 onto the printed-wiring board 60 and to switch the directional control valve 220. There will be described a change in the pressure of the suction nozzle 190 during a time period from a moment at which the electronic component 38 is held by suction by the suction nozzle 190, to a moment at which the electronic component 38 is released from the suction nozzle 190 after the electronic component 38 is placed on the board 60.

It will be understood from FIGS. 10 and 11 that the switching action of the directional control valve 220 from the negative-pressure applying state to the positive-pressure applying state is initiated with the abutting contact of the spool 304 with the switching member 380, before the electronic component 38 is brought into contact with and forced against the printed-wiring board 60 by the downward movement of the suction nozzle 190. The reduction of the negative pressure applied to the suction nozzle 190 is initiated before the electronic component 38 contacts the board 60. After the moment of contact of the electronic component 38 with the board 60, the housing 300 of the directional control valve 220 comes into abutting contact with the movable connector member 400, so that the application of the negative pressure to the suction nozzle 190 is terminated, and the application of the positive pressure through the positive-pressure passage 334 is initiated to increase the positive pressure applied to the suction nozzle 190. After the moment of contact of the electronic component 38 with the board 60, the elevator member 238 is further lowered by the distance Ls to its lowermost position at which the directional control valve 220 is located at its lowermost position and is placed in the atmospheric-pressure applying state with its spool 304 located at its uppermost position, so that the suction nozzle 190 is temporarily exposed to the atmospheric pressure, and is then exposed to the positive pressure, whereby the electronic component 38 is released from the suction nozzle 190.

During the downward movement of the elevator member 238 by the distance Ls, the movable connector member 400 is moved downwards by the housing 300 of the directional control valve 220 against the biasing force of the spring 410, and the housing 300 then comes into abutting contact with the switching member 380. From the L3 position at which the housing 300 contacts the switching member 380, the elevator member 238 is further lowered by the distance L3, so that the switching member 380 is lowered against the biasing force of the spring 388.

The elevator member 238 is held at its lowermost position for a predetermined time and is then elevated. During the upward movement of the elevator member 238 by the distance Ls, the suction nozzle 190 is not elevated until the suction nozzle 190 has been moved, by the biasing force of the spring 202, relative to the nozzle holder 174 to its lowermost or fully lowered position defined by the abutting contact of the pin 204 with the lower end 208. Then, the upward movement of the suction nozzle 190 is initiated, and the suction nozzle 190 is moved away from the electronic component 38.

The switching member 380 is moved upwards by the biasing force of the spring 388 by the distance L3 as the housing 300 of the directional control valve 220 is moved upwards with the elevator member 238. The upward movement of the switching member 380 is terminated by the abutting contact of the flange 390 with the lower surface 392. Subsequently, only the movable connector member 400 which has been lowered from its uppermost position to its lowermost position and which is radially offset from the spool 304 is moved upwards by the biasing force of the spring 410, by the distance L2, together with the housing 300 of the directional control valve 220. Namely, even after the spool 304 has moved apart from the switching member 380 during the upward movement of the housing 300 relative to the bracket 374, the movable connector member 400 is held in abutting contact with the first connecting portion 338 of the housing 300, while maintaining fluid communication between the positive-pressure passages 334, 420, until the shoulder surface 412 of the movable connector member 400 comes into abutting contact with the shoulder surface 414 of the switching member 380. During this relative movement of the housing 300 and the bracket 374, the spool 304 is held in its uppermost position by the force of friction between the O-rings 310-314 and the inner circumferential surface of the valve hole 302, so that the directional control valve 220 is held in its atmospheric-pressure applying state, whereby the positive pressure is kept applied to the suction nozzle 190. This arrangement permits the suction nozzle 1290 to release the electronic component 38 with high operating stability, while holding the electronic component 38 on the component-mounting surface 84 of the printed-wiring board 60.

When the directional control valve 220 has been moved upwards by a total distance of (L2+L3) from its lowermost position, the movable connector member 400 has been moved to its uppermost position by the biasing force of the spring 410. A further upward movement of the directional control valve 220 causes the housing 300 to be separated from the movable, connector member 400, so that the positive-pressure passages 334, 420 are disconnected from each other, with a result of termination of the positive pressure application to the suction nozzle 190. Thus, the positive-pressure passages 334, 420 are kept in communication with each other to maintain the positive pressure application to the suction nozzle 190 during the upward movement of the movable connector member 400 by the distance L2 even after the separation of the housing 300 away from the switching member 380.

It will be understood that the application of the positive pressure to the suction nozzle 190 is terminated by separation of the directional control valve 220 (housing 300) from the movable connector member 400 (connecting portion 402), when the suction nozzle 190 has been elevated to a position which is spaced from the electronic component 38 by a distance of (L2+L3−Ls), which is sufficient to prevent the suction nozzle 190 to pick up the once mounted electronic component 38 by suction due to pressure pulsation which may take place upon removal of the positive pressure from the suction nozzle 190. The distance (L2+L3−Ls) is at least 0.4 mm, preferably, at least 0.5 mm, at least 0.6 mm, at least 0.8 mm, for example, which is suitably selected depending upon related parameters such as the velocity of the upward movement of the suction nozzle 190.

If the positive pressure application to the suction nozzle 190 is terminated immediately after the directional control valve 220 has been separated from the switching member 380 as a result of the upward movement of the valve 220 by the distance L3, without a subsequent upward movement of the movable connector member 440 with the valve 220, the suction nozzle 190 would be still in substantial contact with the electronic component 38. In this case, the reduction of the pressure of the suction nozzle 190 would be initiated before the suction nozzle 190 is moved apart from the electronic component 38, as indicated by two-dot chain line in FIG. 10, so that there is a risk that the electronic component 38 placed on the printed-wiring board 60 is sucked again by the suction nozzle 190 due to pressure pulsation which may take place upon termination of the positive pressure application to the suction nozzle 190.

In the present electronic-component mounting system 12, however, the movable connector member 40 is kept in contact with the directional control valve 220 so as to maintain the positive pressure application to the suction nozzle 190 even after the directional control valve 220 has been moved apart from the switching member 380. This arrangement provides a sufficient distance of the suction nozzle 190 away from the electronic component 38 when the positive pressure application to the suction nozzle 190 is terminated by disconnection of the positive-pressure passages 334, 420. Accordingly, the pressure pulsation indicated above will not cause the suction nozzle 190 to pick up the electronic component 38 by suction. Namely, the distance L2 of projection of the movable connector member 400 from the switching member 380 is determined to enable the suction nozzle 190 to be spaced apart from the electronic component 38 by a distance large enough to prevent the electronic component 38 from being sucked again by the suction nozzle 190 due to the pressure pulsation. In other words, the positive pressure is kept applied to the suction nozzle 190 after the moment of separation of the housing 300 from the switching member 380, for a time length enough to permit the suction nozzle 190 to be elevated to a position at which the suction nozzle 190 is unlikely to pick up the electronic component 38 again by suction. This time length is determined by taking account of the velocity at which the suction nozzle 190 is elevated.

After the directional control valve 220 has been moved apart from the movable connector member 400, the positive-pressure passages 334, 420 are disconnected from each other, so that the positive-pressure passage 334 is exposed again to the atmosphere, with a result of the suction nozzle 190 being exposed to the atmospheric pressure. Thus, the positive-pressure passage 334 of the directional control valve 220 placed in the atmospheric-pressure applying state of FIG. 8 is selectively communicated with the atmosphere and the positive pressure source in the form of the air pump 432. In this respect, the directional control valve 220 placed in the atmospheric-pressure applying state may be considered to be placed in a positive-pressure applying state while the positive-pressure passage 334 is in communication with the positive-pressure passage 420 of the movable connector member 400.

The solenoid-operated shut-off valve 434 connected to the air pump 432 may be closed after the disconnection of the positive-pressure passage 334 from the positive-pressure passage 420, to remove the positive pressure from the movable connector member 400 each time the electronic component 38 has been mounted on the board 60. Alternatively, the shut-off valve 434 may be held open during the component-mounting operation, that is, may be closed at the end of the component-mounting operation of mounting the predetermined electronic components 38 on the board 60 in question, or upon setup changeover of the system 12.

When all of the predetermined electronic components 38 have been mounted on the printed-wiring board 60 in question, the board 60 is unloaded from the PWB holding device 18 onto the board unloading device, and the new board 60 is loaded from the board loading device onto the PWB holding device 18.

It will be understood from the foregoing description of the first embodiment of the invention that a nozzle-pump passage connecting the suction nozzle 190 and the air pump 432 to each other consists of a downstream passage and an upstream passage. The downstream passage is defined by the positive-pressure passage 334 formed through the housing 300, and the passage 210 formed through the nozzle holder 174, etc. The upstream passage of the nozzle-pump passage is defined by the positive-pressure passage 420, annular passage 422, passages 426, 428, connector member 430, passage connecting the connector member 430 and the air pump 432, etc. The connecting portion 338 of the housing 300 constitutes a first connecting portion which is formed at the upstream end of the downstream passage of the nozzle-pump passage, while the movable connector member 400 provides a second connecting portion formed at the downstream end of the upstream passage of the nozzle-pump passage. It will also be understood that the directional control valve 220, head elevating and lowering device 232, elevator member 238, switching member 380, movable connector member 400 and spring 410 cooperate with each other to constitute a communication control device arranged such that the movable connector member 400 is moved upwards by the biasing force of the spring 410 from its lowermost position (at which the movable member 400 projects from the switching member 380 by the distance L2) to its uppermost position, together with the directional control valve 220 during its upward movement with the suction nozzle 190 by the head elevating and lowering device 232, even after the directional control valve 220 has been moved apart from the switching member 380, so that the positive pressure is kept applied to the suction nozzle during the upward movement of the movable connector member 400 by the biasing force of the spring 410 to its uppermost position. The communication control device cooperates with the air pump 432 to constitute the positive-pressure applying device 372 a part of which is provided by the valve switching device 370.

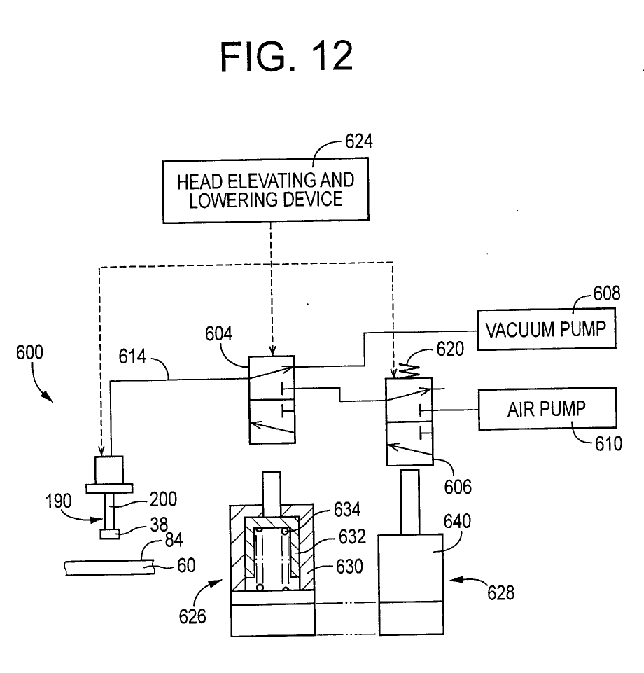

In the illustrated first embodiment described above, a part of the positive-pressure applying device 372 is provided by the valve switching device 370, while another part of the positive-pressure applying device 372 is provided by the directional control valve 220. However, a directional control valve, a valve switching device and a positive-pressure applying device may have a different arrangement relative to each other. An example of this modification will be described as a second embodiment of the invention, by reference to FIG. 12. The same reference signs as used in the first embodiment will be used to identify the corresponding elements, redundant description of which will not be provided. As schematically shown in FIG. 12, an electronic-component mounting system 600 according to the present second embodiment includes two directional control valves 604, 606 which are operated to selectively connect the suction nozzle 190 to a negative pressure source in the form of a vacuum pump 608, a positive pressure source in the form of an air pump 610 and the atmosphere.

The directional control valve 604 is provided in a connecting passage 614 connecting the suction nozzle 190 and the vacuum pump 608, and is connected to the directional control valve 606 as well as the suction nozzle 190 and the vacuum pump 608. The directional control valve 604 is connected to the air pump 610 and the atmosphere as well as the directional control valve 604.

The directional control valve 604 has a negative-pressure applying state for communication of the suction nozzle 190 to the vacuum pump 608, and an atmospheric-pressure/positive-pressure applying state for connection with the directional control valve 606, for selective communication with the air pump 610 or the atmosphere through the directional control valve 606. The directional control valve 604 has a spool which is movable to two positions corresponding to the negative-pressure applying state and the atmospheric-pressure/positive-pressure applying state, respectively.

The directional control valve 606 has a positive-pressure applying state for communication of the suction nozzle 190 with the air pump 610 through the directional control valve 604, and an atmospheric-pressure applying state for communication of the suction nozzle 190 to the atmosphere through the directional control valve 604. The directional control valve 606 has a spool which is biased by a spring toward a position corresponding to the atmospheric-pressure applying state.

The selected suction nozzle 190 is elevated and lowered by a head elevating and lowering device 624. The directional control valves 604, 606 are attached to an elevator member of the head elevating and lowering device 624, and are vertically movable with the suction nozzle 190. The directional control valves 605, 606 are switched by respective stationary valve switching devices 626, 628 during the vertical movements of the suction nozzle 190 by the head elevating and lowering device 624.

The valve switching device 626 for switching the directional control valve 604 between the negative-pressure applying state and the atmospheric-pressure/positive-pressure applying state includes a switching member 632 fitted in a housing 630 movably in the axial or vertical direction. The valve switching device 626 further includes an elastic member in the form of a compression coil spring 632 serving as a biasing device for biasing the switching member 632 so that an upper end portion of the switching member 632 normally projects from the housing 630 toward the spool of the directional control valve 604. The valve switching device 628 for switching the directional control valve 606 between the atmospheric-pressure applying state and the positive-pressure applying state includes a switching member 640 for abutting contact with the spool of the directional control valve 606. The two valve switching devices 626, 628 may be attached to a single stationary member as indicated by two-dot chain line in FIG. 12, or to respective two stationary members.

When the downward movement of the suction nozzle 190 by the head elevating and lowering device 624 to mount the electronic component 38 on the printed-wiring board 60 is initiated, the directional control valve 604 is placed in the negative-pressure applying state, while the directional control valve 606 is placed in its atmospheric-pressure applying state. Since a distance between the spool of the directional control valve 606 and the switching member 640 of the corresponding valve switching device 628 is smaller than a distance between the spool of the directional control valve 604 and the switching member 632 of the corresponding valve switching member 626, the directional control valve 606 is first switched from the atmospheric-pressure applying state to the positive-pressure applying state during the downward movement of the suction nozzle 190. That is, the spool of the directional control valve 606 first comes into abutting contact with the switching member 640, and moves the spool in the upward direction against the biasing force of the spring 620.

Then, the electronic component 38 is placed on the printed-wiring board 60. Thus, the directional control valve 606 is made ready for applying a positive pressure to the suction nozzle 190, before the electronic component 38 is forced onto the board 60. During a further downward movement of the directional control valve 604, the spool of this valve 604 comes into abutting contact with the switching member 632 of the valve switching device 626, to switch the directional control valve 604 to the atmospheric-pressure/positive-pressure applying state, so that the suction nozzle 190 is communicated with the air pump 610 through the directional control valves 604, 606, and supplied with the compressed air delivered from the air pump 610. More specifically, the positive pressure is applied to the suction nozzle 190 after the electronic component 38 has been placed on the board 60. When the directional control valve 604 is located at its lowermost position as a result of the downward movement of the elevator member, the switching member 632 has been slightly moved from its uppermost position against the biasing force of the spring 634, so that the directional control valve 604 is held in its atmospheric-pressure/positive-pressure applying state under the biasing action of the spring 634.

When the suction nozzle 190 is elevated by the head elevating and lowering device 624, the suction nozzle 190 is separated from the electronic component 38, and the directional control valve 604 is moved upwards apart from the switching member 632. The directional control valve 604 is held in its atmospheric-pressure/positive-pressure applying state with its spool kept at its uppermost position (to which the spool was moved during the downward movement of the valve 604). The directional control valve 606 is also moved upwards away from the switching member 640, so that the spool of the valve 606 is permitted to be moved by the biasing force of the spring 620, whereby the valve 606 is switched from the positive-pressure applying state to the atmospheric-pressure applying state.

As described above, the spool of the directional control valve 606 first comes into abutting contact with the switching member 640 during the downward movement of the suction nozzle 190 to mount the electronic component 38 onto the printed-wiring board 60. That is, the switching action of the directional control valve 606 from the atmospheric-pressure applying state to the positive-pressure applying state is first initiated during the downward movement of the suction nozzle 190. Accordingly, the switching action of the directional control valve 606 from the positive-pressure applying state to the atmospheric-pressure applying state by the separation of its spool from the switching member 640 is completed during the upward movement of the suction nozzle 190, after the spool of the directional control valve 604 is separated from the switching member 632 of the valve switching device 626. Therefore, the positive pressure is kept applied to the suction nozzle 190 even after the spool of the directional control valve 604 is moved apart from the switching member 632. Accordingly, when the positive pressure application to the suction nozzle 190 is terminated with the switching action of the directional control valve 606 to the atmospheric-pressure applying state, the suction nozzle 190 is located at a position which is spaced from the electronic component 38 in the upward direction by a distance sufficient to prevent the suction nozzle 190 from sucking again the electronic component 38 by suction due to pressure pulsation upon removal of the positive pressure from the suction nozzle 190. It will be understood that the directional control valve 606, the valve switching device 628 and the air pump 610 cooperate to constitute a positive-pressure applying device in the present second embodiment.

The directional control valve 604 may be switched to the atmospheric-pressure/positive-pressure applying state when the electronic component 38 has been lowered to a position close to the printed-wiring board 60, so that the positive pressure application to the suction nozzle 190 is initiated before the electronic component 38 comes into abutting contact with the board 60.

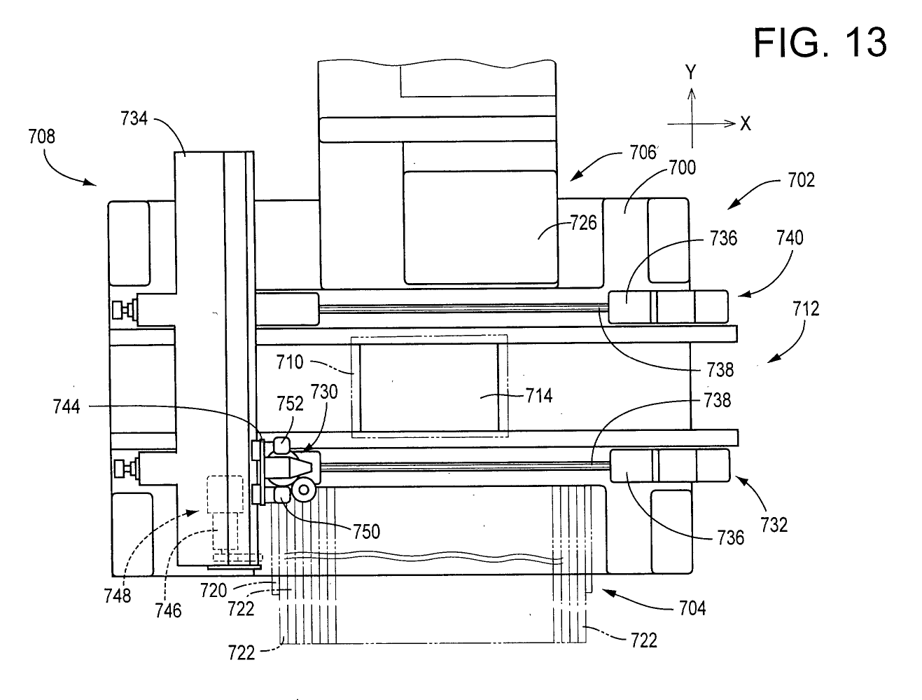

While the sixteen mounting heads 192 are turned about the vertical common axis by the indexing body 120 in the embodiments described above, the principle of the present invention is applicable to an electronic-component mounting system which uses a mounting head that is arranged to be movable in the X-axis and Y-axis directions by an XY positioning device in an XY plane parallel to the plane of a printed-wiring board. An example of this type of electronic-component mounting system will be described as a third embodiment of this invention, by reference to FIG. 13. This mounting system is constructed as disclosed in Japanese Patent No. 2824378.

Referring to FIG. 13, the electronic-component mounting system according to the third embodiment is shown generally at 702. The electronic-component mounting system 702 has a main body in the form of a machine base 700. The present electronic-component mounting system 702 includes a component-supplying device 704, a component-supplying device 706, a component-mounting device 708, a printed-wiring-board holding device (PWB holding device) 710, and a printed-wiring-board conveyor (PWB conveyor) 712, which are mounted on the machine base 700. The PWB holding device,710 includes a PWB supporting unit which is similar to the PWB supporting unit 62 used in the electronic-component mounting system 12 and which includes a PWB supporting device similar to the PWB supporting device 100 and an elevating and lowering device similar to the elevating and lowering device 102. The PWB holding device 710 is provided within a span of the PWB conveyor 712, to support a printed-wiring board 714 such that the board 714 is parallel to the horizontal direction.

The component-supplying devices 704, 706 are spaced from each other in a Y-axis direction perpendicular to an X-axis direction (right and left direction as seen in FIG. 13) in which the printed-wiring board 714 is moved by the PWB conveyor 712. The two component-supplying devices 704, 706 are located on the opposite sides of the PWB conveyor 712, as shown in FIG. 13. The component-supplying device 704 is of tape feeder type which is stationary and has a stationary feeder carriage 720 and a plurality of tape feeders 722. The component-supplying device 706 is of tray type which is also stationary and has a plurality of component trays 726 for accommodating electronic components.

The component-mounting device 708 includes a mounting head 730 and an XY robot 732. The mounting head 730 has a suction nozzle and a nozzle holder. The XY robot 732 includes an X-axis slide 734, an X-axis positioning device 740, a Y-axis slide 744 mounted on the X-axis slide 734, and a Y-axis positioning device 748. The X-axis positioning device 740 is arranged to move the X-axis slide 734 in the X-axis direction, and includes a drive source in the form of an X-axis drive motor 736, a feedscrew (not shown) in the form of a ballscrew 738, and a ballnut engaging the ballscrew 738. The Y-axis positioning device 748 is arranged to move the Y-axis slide 744 in the Y-axis direction, and includes a drive source in the form of a Y-axis drive motor 746, a ballscrew and a ballnut, which are not shown.

The mounting head 730 is mounted on the Y-axis slide 744 such that the mounting head 730 is rotatable about its vertical axis and is axially movable by a head elevating and lower device 750 provided on the Y-axis slide 744, to receive an electronic component from a selected one of the component-supplying devices 704, 706, and mount the electronic component on the printed-wiring board 714. The mounting head 730 is rotated about its axis by a head rotating device 752 provided on the Y-axis slide 744, to perform various operations, such as an operation to rectify the angular position of the electronic component as held by the suction nozzle. The head elevating and lowering device 750 includes a drive source in the form of an electric motor such as a servo motor, or a fluid-operated actuator such as a fluid-operated cylinder, for instance, an air cylinder.

Like the suction nozzles 190 used in the preceding embodiments, the suction nozzle mounted on the mounting head 730 is arranged to hold the electronic component by suction under a negative pressure. When the electronic component is mounted on the printed-wiring board 714, a positive pressure is applied to the suction nozzle. Normally, the suction nozzle 190 is exposed to the atmosphere. To operate the suction nozzle of the mounting head 730, the Y-axis slide 744 is provided with a directional control valve, a valve switching device and a positive-pressure applying device, which are similar to the directional control valve 220, valve switching device 370 and positive-pressure applying device 372, which are provided in the preceding embodiments. The directional control valve is switched by the valve switching device, in timed relationship with a vertical movement of the suction nozzle. When the suction nozzle is elevated by the head elevating and lowering device 750 after the electronic component has been mounted on the printed-wiring board 714, a positive pressure is held applied to the suction nozzle even after the switching member of the valve switching device is spaced apart from the directional control valve, until the suction nozzle is spaced apart from the electronic component by a distance sufficient to prevent the suction nozzle to pick up the once mounted electronic component by suction due to pressure pulsation which may take place upon removal of the positive pressure from the suction nozzle.

In the first embodiment of FIGS. 1-11, the positive-pressure passages 334, 420 may be communicated with each other to initiate the application of a positive pressure to the positive-pressure passage 334, before a switching action of the directional control valve 220 is initiated by abutting contact of the spool 304 of the directional control valve 220 with the switching member 380.

The principle of the present invention is applicable to electric-component mounting devices or systems of any types other than the electronic-component mounting devices or systems described above, and an electric-component mounting method to be practiced by such electric-component mounting devices or systems.

It is to be understood that the present invention may be embodied with various other changes, modifications and improvements, such as those described in the SUMMARY OF THE INVENTION, which may occur to those skilled in the art, without departing from the spirit and scope of the invention defined in the following claims:

[image]

[image]

What is claimed is:

1. A method of mounting an electric component on a component-mounting surface such that the electric component held by a suction nozzle by suction under a negative pressure is forced onto the component-mounting surface, with termination of application of the negative pressure to the suction nozzle, and the suction nozzle is then moved away from said component-mounting surface, said method comprising the steps of:
initiating application of a positive pressure to a passage communicating with said suction nozzle, before said electric component is forced onto said component-mounting surface;
maintaining the application of said positive pressure to said passage, until said suction nozzle is spaced apart from said electric component by at least 0.4 mm; and
then exposing said passage to the atmosphere.

2. A method of mounting an electric component on a component-mounting surface, wherein a suction nozzle holding the electric component by suction under a negative pressure is lowered by a nozzle elevating and lowering device, to force the electric component onto the component-mounting surface, such that said nozzle elevating and lowering device moves at least one of a directional control valve and a switching member to move said directional control valve and said switching member toward each other, for thereby causing said switching member to switch said directional control valve from a negative-pressure applying state for applying the negative pressure to said suction nozzle, to an atmospheric-pressure applying state for applying an atmospheric pressure to said suction nozzle, and wherein said suction nozzle is subsequently elevated by said nozzle elevating and lowering device such that said nozzle elevating and lowering device moves said directional control valve and said switching member away from each other, said method comprising the steps of:
initiating application of a positive pressure to said suction nozzle, when said directional control valve is switched from said negative-pressure applying state to said atmospheric-pressure applying state; and
maintaining the application of said positive pressure to said suction nozzle, even after said directional control valve and said switching member have been moved away from each other as a result of initiation of an operation of said nozzle elevating and lower device to elevate said suction nozzle.

3. A method according to claim 2, wherein said directional control valve is switched between said negative-pressure and atmospheric-pressure applying states by said switching member, by movements of said directional control valve by said nozzle elevating and lowering device while said switching member is held stationary.

4. An electric-component mounting system for mounting an electric component on a component-mounting surface, comprising:
a suction nozzle operable to hold the electric component by suction under a negative pressure;
a nozzle elevating and lowering device operable to elevate and lower said suction nozzle to place the electric component on the component-mounting surface;
a negative pressure source operable to generate said negative pressure;
a directional control valve provided in a connecting passage connecting said negative pressure source and said suction nozzle, and having at least a negative-pressure applying state for applying the negative pressure from said negative pressure source to said suction nozzle, and an atmospheric-pressure applying state for applying an atmospheric pressure to said suction nozzle;
a valve switching device including a switching member which is positioned relative to said directional control valve such that said nozzle elevating and lowering device moves at least one of said directional control valve and said switching member to move said directional control valve and said switching member toward each other, for thereby causing said switching member to switch said directional control valve from said negative-pressure applying state to said atmospheric-pressure applying state, in synchronization with a movement of said suction nozzle by said nozzle elevating and lowering device; and
a positive-pressure applying device including a positive pressure source operable to generate a positive pressure, and operable to initiate application of the positive pressure to said suction nozzle, when said directional control valve is switched from said negative-pressure applying state to said atmospheric-pressure applying state, said positive-pressure applying device maintaining the application of said positive pressure to said suction nozzle, for a predetermined time after said directional control valve and said switching member have been moved away from each other as a result of initiation of an operation of said nozzle elevating and lowering device to elevate said suction nozzle.

5. An electric-component mounting system according to claim 4, wherein said positive-pressure applying device includes:
a first connecting portion formed at an upstream end of a downstream passage connected to said suction nozzle,
a second connecting portion formed at a downstream end of an upstream passage connected to said positive pressure source, said connecting passage consisting of said downstream and said upstream passages; and
a communication control device operable by said nozzle elevating and lowering device, when said directional control valve is switched from said negative-pressure applying state to said atmospheric-pressure applying sate, to effect an abutting contact of said first and second connecting portions with each other for communication of said upstream and downstream passages with each other, said communication control device maintaining the application of said positive pressure to said suction nozzle for said predetermined time after said directional control valve and said switching member have been moved away from each other.

6. An electric-component mounting system according to claim 4, wherein said directional control valve includes:
a housing; and
a spool disposed within said housing, movably by said switching member relative to said housing, to selectively establish said negative-pressure applying state and said atmospheric-pressure applying state.

7. An electric-component mounting system according to claim 6, wherein said housing includes a first connecting portion having a positive-pressure passage which communicates with a downstream passage connected to said suction nozzle, said positive-pressure passage being formed in said first connecting portion such that said positive-pressure passage is open in said first connecting portion to apply the positive pressure to said suction nozzle through said positive-pressure passage and said downstream passage.

8. An electric-component mounting system according to claim 7, wherein said valve switching device includes:
said switching member; and
a holding member for holding said switching member such that said holding member and said housing of said directional control valve are moved relative to each other by said nozzle elevating and lowering device, said holding member being provided with a second connecting portion having a surface for abutting contact with a surface of said first connecting portion in which said positive-pressure passage is open.

9. An electric-component mounting system according to claim 8, wherein each of at least one of said first and second connecting portions consists of a movable connector member which is movable in a direction of relative movement of said directional control valve and said switching member, relative to a member which holds at least one of said housing and said holding member.

10. An electric-component mounting system according to claim 9, wherein said positive-pressure applying device includes a biasing device for biasing said movable connector member in a direction toward the other of said first and second connecting portions, and a stop device for defining a fully advanced position at which said movable connector member is held under a biasing action of said biasing device, said fully advanced position being such that said movable connector member and said other of said first and second connecting portions are held in abutting contact with each other even after said switching member and said spool of said directional control valve have been moved away from each other during the relative movement of said holding member and said housing away from each other.

11. An electric-component mounting system according to claim 8, wherein said switching member is held by said holding member such that said switching member is movable relative to said holding member.

12. An electric-component mounting system according to claim 11, wherein said valve switching device further includes a biasing device disposed between said switching member and said holding member, for biasing said switching member in a direction toward said spool of said directional control valve, and a stopper device for defining a fully advanced position at which said switching member is held under a biasing action of said biasing device.

13. An electric-component mounting system according to claim 9, wherein said second connecting portion consists of said movable connector member movable relative to said holding member.

14. An electric-component mounting system according to claim 13, wherein said switching member is held by said holding member such that said switching member is movable relative to said holding member, and said movable connector member is held by said switching member such that said movable connector member is movable relative to said switching member, in a direction of the relative movement of said switching member and said holding member.

15. An electric-component mounting system according to claim 14, wherein said switching member includes a cylindrical hollow portion at which said switching member is held by said holding member, and said movable connector member is movably fitted in said cylindrical hollow portion.

16. An electric-component mounting system according to claim 15, wherein said valve switching device includes a first biasing device for biasing said switching member, and said positive-pressure applying device includes a second biasing device for biasing said movable connector member, said first and second biasing devices including respective first and second coil springs which are disposed coaxially with each other.

17. An electric-component mounting system according to claim 4, wherein said switch member of said valve switching device is stationary, and said directional control valve is movable by said nozzle elevating and lowering device, relative to said switching member, to cause said switching member to switch said directional control valve from said negative-pressure applying state to said atmospheric-pressure applying state.

18. An electric-component mounting system according to claim 4, further comprising a substrate-holding device operable to hold a circuit substrate which has said component-mounting surface.
